(19) United States
(12) Patent Application Publication
(10) Pub. No.: US 2019/0053397 A1
(43) Pub. Date: Feb. 14, 2019

(54) IDENTIFYING A LOCATION OF A RESOURCE IN A DATA CENTER RACK

(71) Applicant: Intel Corporation, Santa Clara, CA (US)

(72) Inventors: Thane M. Larson, Portland, OR (US); Vasudevan Srinivasan, Portland, OR (US); Murugasmy K. Nachimuthu, Beaverton, OR (US); Brian J. Griffith, Bonney Lake, WA (US)

(21) Appl. No.: 15/870,721

(22) Filed: Jan. 12, 2018

(51) Int. Cl. H05K 7/14

(52) U.S. Cl. CPC H05K 7/1498; H05K 7/1459; H05K 7/1497

(57) ABSTRACT

The present disclosure describes a number of embodiments related to devices, systems, and methods for identifying a location of a resource among a plurality of locations in a data center rack. A signal transmission medium may be disposed proximate to the plurality of locations to transmit a signal traversing the plurality of locations, with each resource in the rack having a sensor or transmitter portion that couples itself to the signal transmission medium at a point substantially at this resource location, or the location of the resource within the data center rack is identified based at least in part on the sensed signal.

### TECHNICAL FIELD

Embodiments of the present disclosure generally relate to the field of data centers. More specifically, embodiments of the present disclosure relate to devices and methods for locating a position of a compute resource within a data center rack, e.g., a compute resource, a network resource or a storage resource.

### BACKGROUND

Over the last several years there has been a rapid increase in both the number and the scale of data centers that may house large numbers of computing components, in particular servers, in a large number of data center racks. In particular, very large data centers that serve cloud-based computing demands around the world are increasing in both size and number of locations. It is not uncommon to have thousands of data center racks in a location, with each data center rack able to hold 10 or more servers.

As a result, it is often challenging to identify the location of a particular resource, such as a compute resource (e.g., a server), a network resource (e.g., a switch) or a storage resource (e.g., a solid state drive) in a data center rack that may need replacing, or some other action based upon a location of the resource in the data center rack. This is especially true when the location of a resource may be frequently changed as a part of data center operations of adding or relocating servers, switches, data storage, or other components within multiple data center racks. Typically, identifying the location of a resource within a rack has been costly, time-consuming, and error-prone, and is frequently done manually with visual inspection.

### BRIEF DESCRIPTION OF THE DRAWINGS

Embodiments will be readily understood by the following detailed description in conjunction with the accompanying drawings. To facilitate this description, like reference numerals may designate like structural elements. Embodiments are illustrated by way of example and not by way of limitation in the figures of the accompanying drawings.

FIG. 1 is a diagram of an example data center rack with a Signal Transmission Medium (STM) traversing the data center rack and connected with a Rack Management Module (RMM), in accordance with various embodiments.

FIGS. 2A-2C illustrate example STMs as a resistive electrical wire, in accordance with various embodiments.

FIG. 3 is a block diagram that illustrates a process for locating a resource within a data center rack using an STM as a resistive electrical wire, in accordance with various embodiments.

FIG. 4 is a diagram of an analog to digital circuit to provide a digital indication of a voltage, in accordance with various embodiments.

FIG. 5 is a diagram that illustrates an STM implemented as a light pipe, in accordance with various embodiments.

FIG. 6 is a schematic illustrating the relationship of a light dependent resister (LDR) module, an RMM, and one or more servers in a data center rack, in accordance with various embodiments.

FIG. 7 is a block diagram that illustrates a process for using signal comparison to identify a location of a server within a data center rack, in accordance with various embodiments.

FIG. 8 is a diagram of a server reflecting a signal on an STM, in accordance with various embodiments.

FIG. 9 is a block diagram that illustrates a process for using signal reflection to identify a location of a resource within a data center rack.

FIG. 10 is a diagram of a time domain reflectometer (TDR) to detect the presence or absence of resources within a data center rack, in accordance with various embodiments.

FIG. 11 is a block diagram that illustrates an STM as a digital bus with data modifiers, in accordance with various embodiments.

FIG. 12 is a block diagram that illustrates a process for using data modifiers to identify a location of a resource within a data center rack, in accordance with various embodiments.

FIG. 13 illustrates an example computing device 1300 suitable for use to practice aspects of the present disclosure, in accordance with various embodiments.

FIG. 14 is a diagram illustrating computer-readable media having instructions for practicing the above-describe techniques, or for programming/causing systems and devices to perform the above-describe techniques, in accordance with various embodiments.

### DETAILED DESCRIPTION

Methods, apparatuses, and systems for identifying a location of a resource among a plurality of locations within a data center rack may be disclosed herein. In embodiments, a resource may include any component that may be stored within a rack or cabinet. In embodiments, an STM may be a medium proximate to a plurality of locations in a data center rack to transmit one or more signals that may traverse the plurality of locations. In embodiments, one of a plurality of resources may either send a signal, receive a signal, reflect the signal, or otherwise interact with the STM at a location substantially at the location of the resource within the plurality of locations in the data center rack. As a result, the physical location of the resource within the plurality of locations in the data center rack may be identified. This location information may be used by data center management software to locate systems and to assign electronic addresses such as Internet protocol (IP) addresses. The location information may also be used to indicate to service personnel the exact location of a server within a rack to aid in replacement of the server or for some other physical interaction with the resource.

In the following description, various aspects of the illustrative implementations are described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following description, reference is made to the accompanying drawings that form a part hereof, wherein like numerals may designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “including,” “having,” and the like, as used with respect to embodiments of the present disclosure, are synonymous.

The terms “coupled with” and “coupled to” and the like may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. By way of example and not limitation, “coupled” may mean two or more elements or devices are coupled by electrical connections on a printed circuit board such as a motherboard, for example. By way of example and not limitation, “coupled” may mean two or more elements/devices cooperate and/or interact through one or more network linkages such as wired and/or wireless networks. By way of example and not limitation, a computing apparatus may include two or more computing devices “coupled” on a motherboard or by one or more network linkages.

Various operations are described as multiple discrete operations in turn, in a manner that is most helpful in understanding the claimed subject matter. However, the order of description should not be construed as to imply that these operations are necessarily order dependent.

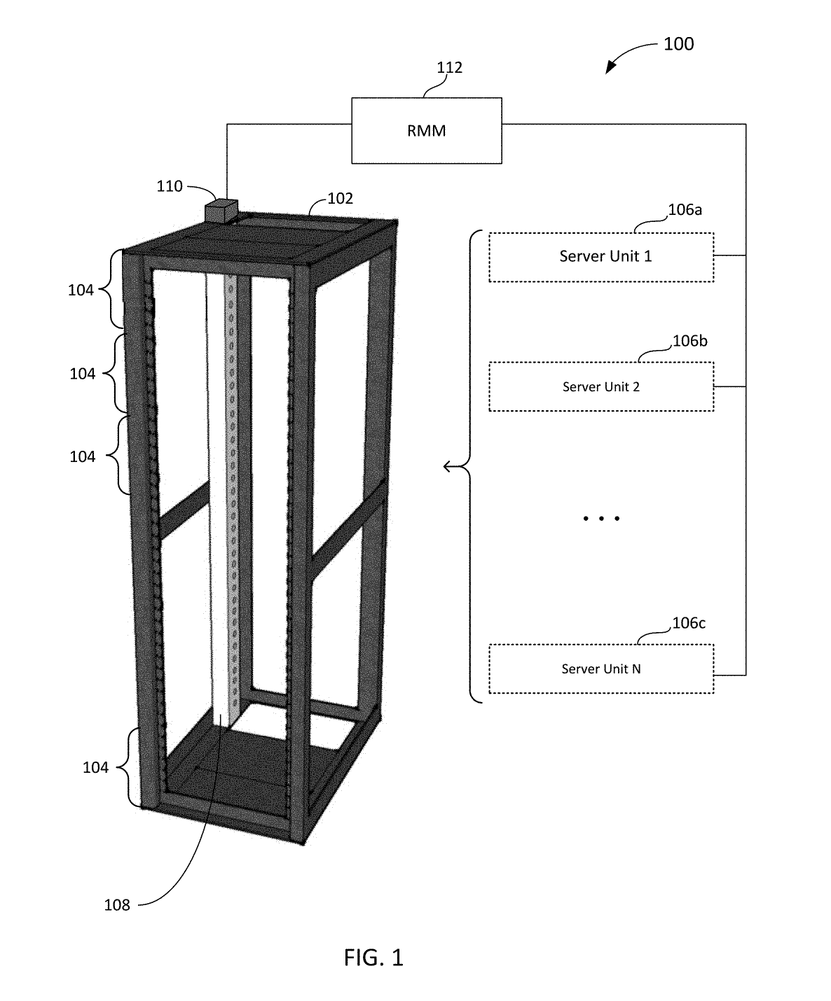

FIG. 1 is a diagram of an example data center rack with a Signal Transmission Medium (STM) traversing the data center rack and coupled with a Rack Management Module (RMM), in accordance with various embodiments. In other embodiments, the RMM functionality may be within a server in the data center rack, a Chassis Management Module (CMM), or some other module outside the data center rack. The RMM functionality may be within a Pod manager at a Pod level that may include a physical collection of multiple racks. Diagram 100 includes a data center rack, which may be referred to herein as a rack 102 that may include multiple locations 104 within the rack 102 into which one or more resources (e.g., computing servers, networking devices, or storage devices) 106a-106c may be respectively placed. In embodiments, the multiple locations 104 may be identified by a drawer, shelf, or a rail (not shown for clarity) that may be attached inside the rack 102 and may be adjustable to accommodate different server heights. In embodiments, the resources (compute, network, or storage) may be employed in the data center as elements of a traditional computing system in the traditional manner. In alternate embodiments, the resources (compute, network, or storage) may be employed as elements of a resource pool of a software defined computing system of the data center.

For ease of understanding, for the remainder of the description, resources 106a-106c may simply be described as servers 106a-106c; however, the description is not limiting, and should be construed as representative examples of a resource. Unless excluded, the description applies equally to other data center resources, networking resources, storage resources, and the like. Furthermore, although embodiments described herein may reference rack or data center racks, the techniques described herein may apply to any other cabinet or other storage space that may have one or more internal locations into which components may be placed.

In embodiments, the multiple locations 104 may be discrete locations along a vertical orientation of the rack 102. In embodiments, the multiple locations 104 may be of varying heights. In embodiments, the heights of the multiple locations 104 may be chosen to accommodate the standardized heights of the servers 106a-106c that may be placed within the rack 102. In embodiments, a standardized height may be expressed as a rack unit (U) that may be 1.75 inches (in) or 44.45 mm in height. For example, a server 106a may be 2U, 3U, etc. in height.

In embodiments, the STM 108 may be placed within the rack 102, and may traverse the multiple locations 104 of the rack 102. In embodiments, the STM 108 may be used to identify the location of one of the servers 106a-106c. In embodiments, the STM 108 may run the length of the rack 102, and be positioned close in distance to one or more of the servers 106a-106c that may be placed respectively at one or more of the locations 104 within the rack 102. In embodiments, the STM 108 may be located substantially orthogonally to the orientation of the one or more servers 106a-106c when inserted in the rack 102.

In embodiments, the STM 108 may be any medium that may be used to propagate a signal. In embodiments, a signal or a wave may be read or sensed at any location along the STM 108 or at discrete locations along the STM 108. In embodiments, a signal or a wave may be transmitted at any location along the STM 108 or at discrete locations along the STM 108. Examples of an STM 108 may include an electrical wire, a light pipe, an optical waveguide, an electromagnetic waveguide, a sound waveguide, a sound pipe, a data bus, or any other appropriate medium that may be used to propagate a signal or wave.

In embodiments, the STM 108 may allow one or more servers 106a-106c located within the rack 102 to couple with or to interact with the STM 108 substantially at the physical locations of the one or more servers 106a-106c within the rack 102.

In embodiments, interactions between the STM 108 and one of the one or more servers 106a-106c may include transmitting a signal onto the STM 108. In embodiments, transmitting a signal may include transmitting: light at various frequencies or amplitudes, electrical current, an acoustical wave, electromagnetic signal, electromagnetic wave, or some other suitable signal. In embodiments, interactions between the STM 108 and one of the one or more servers 106a-106c may include applying a voltage, or to cause a point of reflection within the STM 108 to reflect a signal that may be transmitted along the STM 108. In embodiments, interactions between the STM 108 and one of the one or more servers 106a-106c may include reading a data signal at a point along the STM 108 to extract a data value. Other embodiments may be described more fully below.

In embodiments, a head unit 110 may be coupled with the STM 108 to facilitate transmitting or receiving signals via the STM 108 to or from one of the one or more servers 106a-106c. In embodiments, the head unit 110 may be physically attached to STM 108 or may be physically attached to the rack 102.

In embodiments, the head unit 110 may receive instructions to initiate or transmit signals or waves, or apply other conditions, to the STM 108 as described above. In embodiments, the head unit 110 may receive signals, or may detect, sense, or read other conditions on the STM 108 where the head unit 110 in the STM 108 may be coupled. In embodiments, the head unit 110 may include additional components to facilitate these functions. For example, the head unit 110 may include a LDR or photo resistors that may evaluate the intensity or wavelength of light on a light pipe STM 108 that may have been sent by one of the servers 106a-106c. In embodiments, the head unit 110 may include a digital voltage meter to read a voltage on the STM 108 implemented as a conductive wire.

In embodiments, a rack management module (RMM) 112 may be coupled with the head unit 110. In embodiments, the RMM 112 may facilitate the management of one or more data center racks 102 within a data center. In embodiments, the RMM 112 may send one or more requests or commands to the head unit 110 to initiate one or more processes to determine the location 104 among a plurality of locations of a server 106a.

In embodiments, the RMM 112 may be coupled to one or more of the servers 106a-106c that may be located within the rack 102. In embodiments, there may be a data connection between the RMM 112 and a server 106a, where the RMM 112 and the server 106a may be able to communicate, for example, over TCP/IP, or some other data transmission protocol. In one example, the RMM 112 for rack 102 may be able to communicate with server 106a that is located in the rack 102, but the RMM 112 may not know where in the plurality of locations 104 within the rack 102 the server 106a is physically located. The server 106a may not know where in the plurality of locations 104 within the rack 102 it is located.

In embodiments, the RMM 112 may send one or more requests or commands to a server 106a to initiate one or more processes to determine the location 104 among a plurality of locations 104 of the server 106a. In embodiments, requests or commands may be sent to both head unit 110 and server 106a.

In embodiments, the RMM 112 may receive data from the head unit 110 or from a server 106a. The received data may include an identification of a location 104 among the plurality of locations of the server 106a within the rack 102. In embodiments, the received data may be used by the RMM 112 to identify a location 104 among the plurality of locations 104 of the server 106a within the rack 102. In embodiments, the RMM 112 may be a computing device or a portion of a computing device.

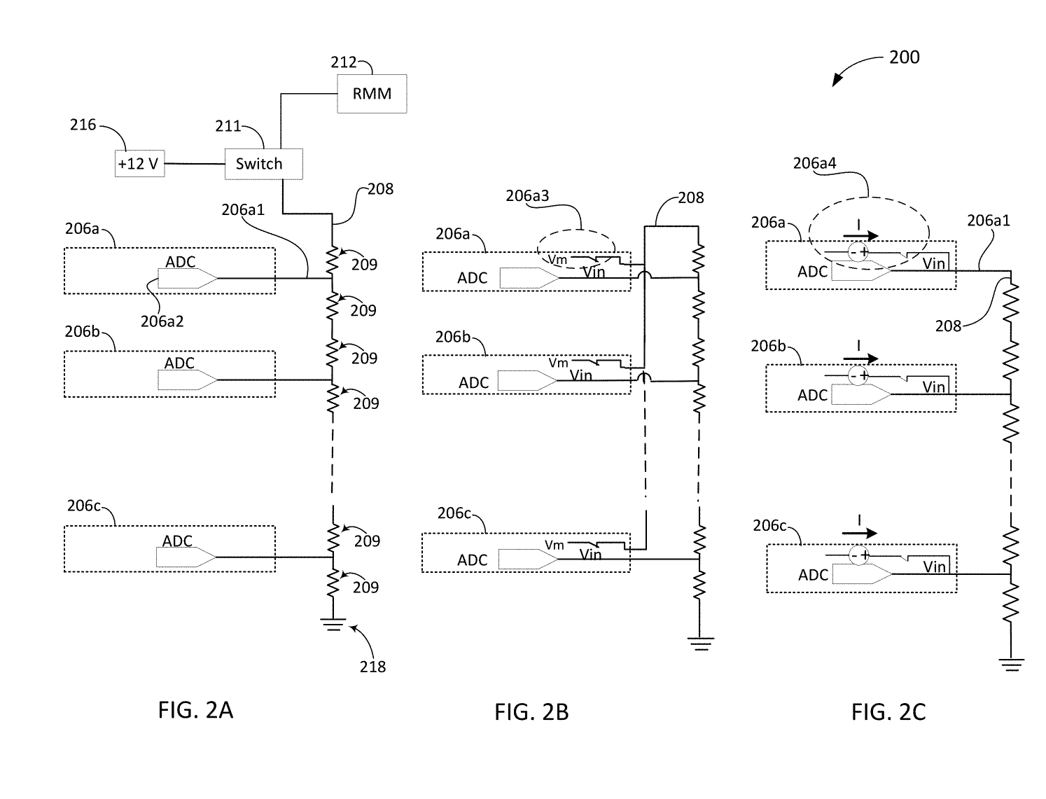

FIGS. 2A-2C illustrate example STMs as a resistive electrical wire, in accordance with various embodiments. FIG. 2A shows a resistive electrical wire 208 that may be similar to the STM 108 of FIG. 1. In embodiments, the resistive electrical wire 208 may be a shared bus bar. In embodiments, the resistive electrical wire 208 may contain one or more resistors 209. In embodiments, the resistors 209 may be evenly spaced along the resistive electrical wire 208. In embodiments, the resistors 209 may be sufficient in number to correspond with the number of possible locations 104 into which a server 106a may be located within the rack 102 of FIG. 1.

In embodiments, each resistor 209 may be positioned on the resistive electrical wire 208 between each possible location 104 within the rack 102 that one of the one or more servers 206a-206c, which may be similar to the servers 106a-106c of FIG. 1, may be located. In embodiments, a server 206a, when located in the rack 102, may couple with the resistive electrical wire 208 using an electrical connection 206a1 located substantially at the location of the server 206a. In embodiments, the electrical connection 206a1 may couple with the resistive electrical wire 208 between resistors 209.

In embodiments, the resistive electrical wire 208 may be a high resistance wire (for example, Kanthal® wire or similar) or a carbon resistor ignition cable that may have determined resistance properties that may be measured in ohms per foot. In one example, the resistance property may be about 4000 ohms per foot.

In embodiments, the resistive electrical wire 208 may have a voltage source 216 at a first location on the resistive electrical wire 208 and a ground 218 at a second location on the resistive electrical wire 208. In embodiments, the voltage source 216 may be located within or may be controlled by the head unit 110 of FIG. 1.

In embodiments, the electrical connection 206a1 for a server 206a may be at a voltage between the voltage at the voltage source 216 and the ground 218. In embodiments, based on the resistance characteristics of the resistive electrical wire 208 between the voltage source 216 at the first location and the ground 218 at the second location, the server 206a may determine its location within the plurality of locations 104 within rack 102.

In embodiments, a server 206a may include an analog to digital converter (ADC) 206a 2 that may provide a numeric indication of a voltage sensed on the electrical connection 206a1. In embodiments, this indication may be used to determine the location of a server 206a among a plurality of locations 104 within the rack 102.

In one embodiment for determining the location of a server, assume there are N locations 104 within a rack 102 and that the resistive electrical wire 208 includes N evenly-spaced resistors 209 each having a resistance of Rm, and Vm is the voltage of the voltage source 216. If server 206a is at a location i, the voltage Vi on the electrical connection 206a1 may be expressed as:

Vi=Vm*(i*Rm)/(N*Rm)=Vm*(i/N) [1]

The location i may then be determined as:

i=N*(Vi/Vm) [2]

Thus, using equation [1], if Vm=5V and i=10, then Vi at height i=10 (i.e., 10^{th} location 104 on the rack counting from the ground 218) would be equal to 1 volt. Conversely, if Vi measured 1 volt, then from equation [2] it would be determined that i=10.

In embodiments, the voltage source 216 may be directly connected to the resistive electrical wire 208. However, this may result in a constant dissipation of power across the wire 208 to the ground 218.

In embodiments, a switch 211 may be placed between the voltage source 216 and the resistive electrical wire 208. In embodiments, the switch 211 may be included within the head unit 110. In embodiments, the switch 211 when closed may cause a voltage to be applied to the resistive electrical wire 208 and when open may cause a voltage to not be applied to the resistive electrical wire 208. In embodiments, the RMM 212, which may be similar to the RMM 112 of FIG. 1, may send open or close instructions to the switch 211. In embodiments, to cause each server 206a-206c to determine its location within the rack 104, the RMM 212 may transmit a request to each server 206a-206c to determine its location. The RMM 212 may then cause the switch 211 to close to provide a voltage to the resistive electrical wire 208. When all servers have identified their respective locations 104 within the rack 102, the RMM 212 may cause the switch 211 to open so that a voltage is no longer applied to the resistive electrical wire 208.

FIG. 2B shows an embodiment where instead of voltage source 216 supplying a voltage to the resistive electrical wire 208 as shown in FIG. 2A, one or more of the individual servers 206a-206c may supply a switched voltage 206a3 to the resistive electrical wire 208. In these embodiments, one of the one or more individual servers 206a-206c may identify its location within the rack 102 without using an outside voltage source 216, the RMM 212, or the switch 211. In embodiments, each server may provide the same reference voltage to the resistive electrical wire 208.

FIG. 2C shows an embodiment where, instead of applying a voltage to the resistive electrical wire 208, one or more of the individual servers 206a-206c may provide a switch to a current source 206a 4 within a server 206a onto its respective electrical couplings 206a1. When the current source 206a 4 is active, the voltage that may be used to determine the location of server 206a may be read from connection 206a1 as described above.

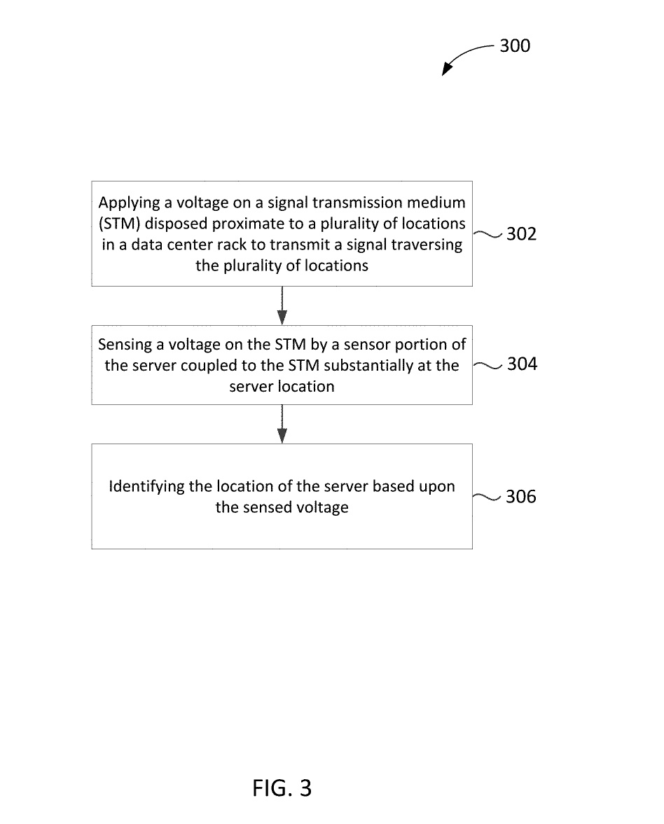

FIG. 3 is a block diagram that illustrates a process for locating a resource (e.g., a server) within a data center rack using an STM as a resistive electrical wire, in accordance with various embodiments. In various embodiments, the RMM 212 of FIG. 2 or servers 206a-206c may perform a portion of, or one or more of, the processes as described in diagram 300.

At block 302, the process may include applying a voltage on an STM disposed proximate to a plurality of locations in the data center rack to transmit a signal traversing the plurality of locations. In embodiments, the STM may refer to the resistive electrical wire 208 of FIG. 2A-2C. In embodiments, the data center rack may refer to rack 102 of FIG. 1, and the plurality of locations may refer to locations 104 of FIG. 1 into which one or more of the servers 106a-106c of FIG. 1 may be located.

In embodiments, a voltage may be placed on the resistive electrical wire 208 by a voltage source 216. The resistive electrical wire 208, in embodiments, may have an electrical resistance through the wire that may be proportional to the length of the wire.

In embodiments, the voltage source 216 may operate continuously. In embodiments, the voltage source 216 may be turned on/off by the switch 211, which may be controlled by the RMM 212. In embodiments, a voltage may be placed on the resistive electrical wire 208 by a voltage source 206a3 from a server 206a of FIG. 2B. In embodiments, a voltage may be placed on the resistive electrical wire 208 by a current source 206a 4 from server 206a of FIG. 2C.

At block 304, the process may include sensing a voltage on the STM by a sensor portion of the server coupled to the STM substantially at the server location. In embodiments, a voltage may be sensed on the resistive electrical wire 208 by a server 206a using the electrical connection 206a1 of FIG. 2A-2C that may be attached to the resistive electrical wire 208 substantially at the location of the server 206a. In embodiments, an ADC 206a 2 may be used to convert the sensed voltage into a numerical value.

At block 306, the process may include identifying the location of the server based upon the sensed voltage. Embodiments, some of which are described above, may include determining the location of the server based upon the known resistive characteristics of the resistive electrical wire 208 and the voltage sensed by a server 206a at a point along that wire. In embodiments, the location of the server may be identified by a U position in the rack 102, by an index of positions 104, or by a distance from a ground, such as ground 218.

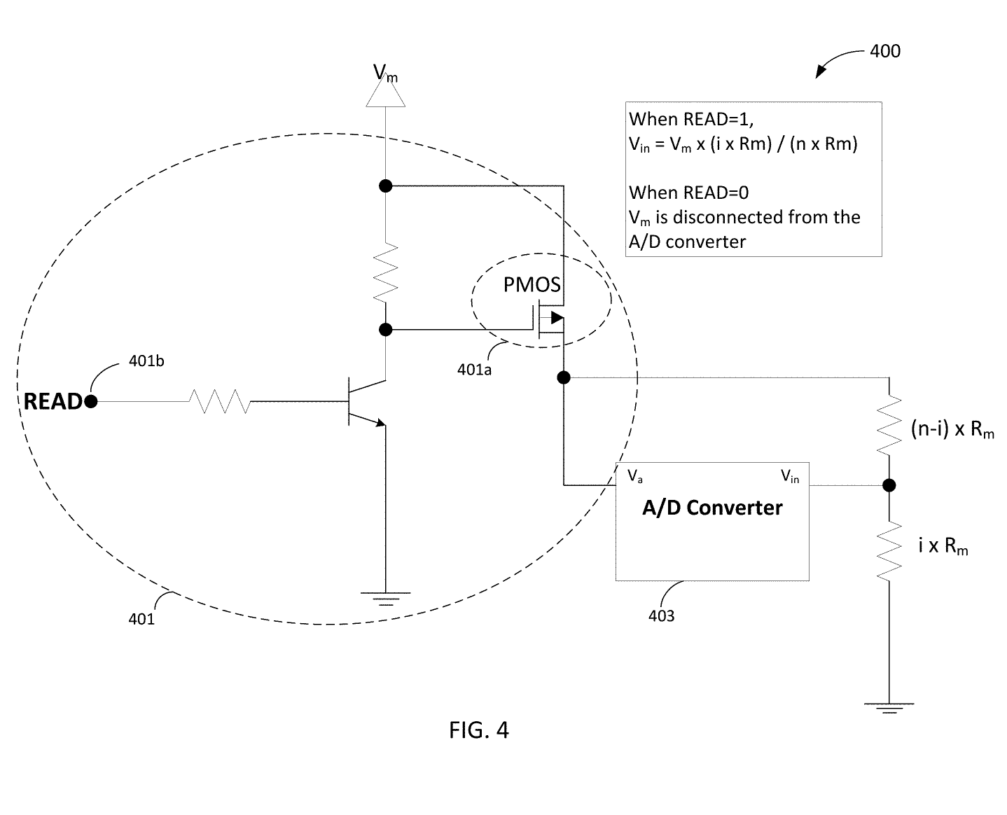

FIG. 4 is a diagram of an analog to digital circuit to provide a digital indication of a voltage, in accordance with various embodiments. Diagram 400 shows one embodiment of an ADC circuit. In embodiments, the ADC circuit 400 may include an ADC 403 and an ADC switch 401 that may be used to turn on the ADC 403 when a voltage is to be read, or to turn off the ADC 403 when a voltage is not to be read. In this way, minimal power may be lost when the ADC circuit 400 is not being used. For example, a P-type metal-oxide semiconductor (PMOS) gate 401a may be used in conjunction with a READ voltage input 401b. When the READ voltage input 401b is “1,” the gate 401a may close and allow power to flow to the ADC 403. When the READ voltage input 401b is “0,” the gate 401a may open and prevent power from flowing to the ADC 403.

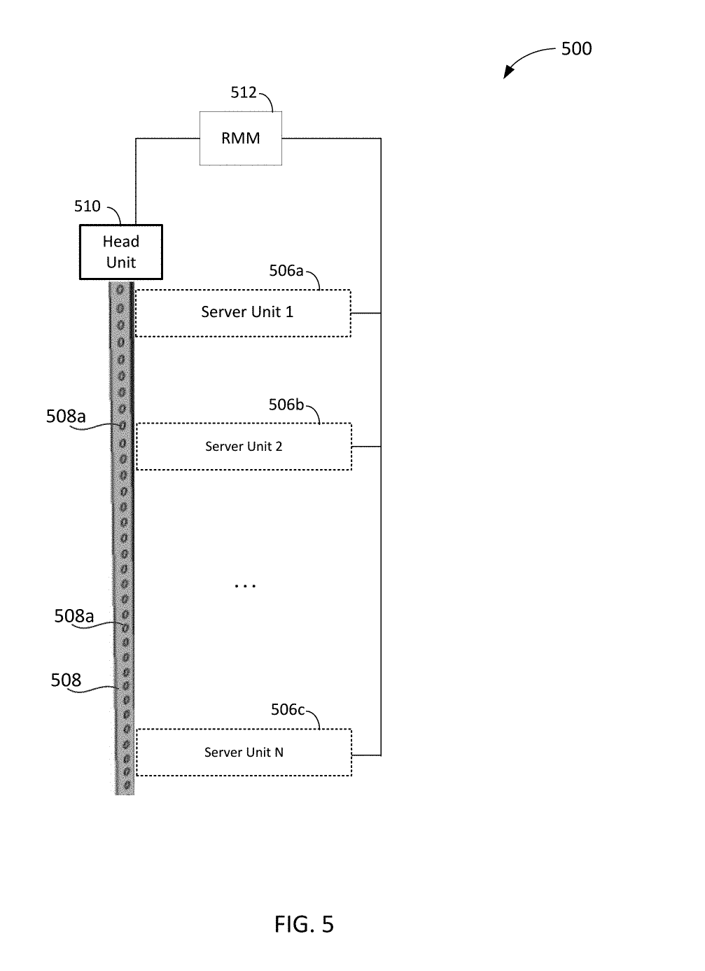

FIG. 5 is a diagram that illustrates an STM implemented as a light pipe, in accordance with various embodiments. Diagram 500 shows a light pipe 508 that may be similar to the STM 108 of FIG. 1. Servers 506a-506c, which may be similar to servers 106a-106c of FIG. 1, may be located respectively in various locations within a rack, which may be similar to the various locations 104 within a rack 102 of FIG. 1. In embodiments, the light pipe 508 may serve as an optical waveguide. In embodiments, light may be propagated through the light pipe 508 in a virtually loss-less manner. In embodiments, the light pipe 508 may have a degree of opacity that may cause attenuation of the light as it travels through the light pipe 508.

In embodiments, the servers 506a-506c may be located adjacent to various locations of the light pipe 508. In embodiments, the servers 506a-506c may be physically connected to or may be able to physically connect to various locations of the light pipe 508. In embodiments, a head unit 510, which may be similar to head unit 110 of FIG. 1, may be coupled with the light pipe 508. In embodiments, the head unit 510 may facilitate the transmission or the reception of a signal along the light pipe 508. In embodiments, an RMM 512, which may be similar to RMM 112 of FIG. 1, may be coupled with the head unit 510 or may be coupled with the servers 506a-506c located in the rack 102.

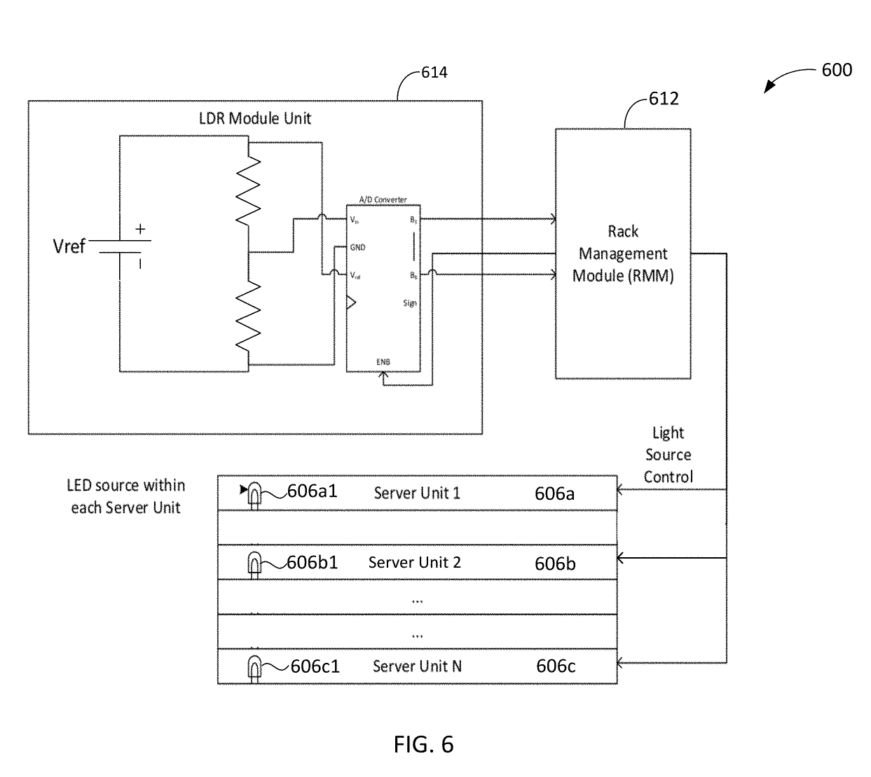

In embodiments, the light pipe 508 may allow various wavelengths or various intensities of light to propagate within the light pipe 508. In embodiments, the light pipe 508 may be substantially orthogonal or substantially adjacent to the servers 506a-506c. In embodiments, light sources, discussed further in FIG. 6, or light sensors (not shown for clarity) may be coupled with the servers 506a-506c and may be to respectively interact with the light pipe 508 at substantially a same location at which each server 506a-506c may be located within the rack 102.

In embodiments, a light signal that may include various wavelengths or various intensities may be generated and transmitted through the light pipe 508. In embodiments, the light signal may be generated from the head unit 510 and travel in a direction toward the servers 506a-506c. In some of these embodiments, the servers 506a-506c may include light sensors that may determine the intensity or other characteristic of the light generated from the head unit 510.

In embodiments, the light signal may be generated by one of the servers 506a-506c and travel toward the direction of a head unit 510. In embodiments, as the light signal travels through the light pipe 508, the signal may become attenuated, or may be altered in some other way. In embodiments, the light pipe 508 may include one or more degrees of opacity so that the attenuation of the light signal may be predictable over a distance the light signal may travel through the light pipe 508.

In embodiments, the light pipe 508 instead may be implemented as either an optical, acoustical, or electromagnetic pipe or waveguide that may carry a light, sound, or electromagnetic signal or wave. In embodiments, the location of one of the servers 506a-506c may be determined to be the identification of a particular signal wavelength or amplitude. In other embodiments, the location of a server may be determined by an attenuation of the signal that may be measured between a source of the signal and the location of one of the servers 506a-506c. The calculation of the attenuation of the signal between the source and the detection of the signal may be used to determine the location among the plurality of locations 104 of the server within the rack 102. In embodiments, the RMM 512 may indicate where the signal may be transmitted or where the signal may be received along the STM.

Turning back now to embodiments of light pipe 508 as a light pipe, in embodiments, the light pipe 508 may be encased by an opaque material with holes or openings 508a in the opaque material. In embodiments, these openings 508a may correspond to a plurality of discrete locations 104 at which a server 506a-506c may be located. In embodiments, the openings 508a may substantially correspond to a U location within the rack 102. In embodiments, a light source from the server may enter the light pipe 508 from within these discrete openings 508a.

FIG. 6 is a schematic illustrating the relationship of an LDR module, an RMM, and one or more servers in a data center rack, in accordance with various embodiments. Diagram 600 shows a LDR module unit 614 that may be coupled to an RMM 612, which may be similar to RMM 112 of FIG. 1. In embodiments, the LDR module unit 614 may be coupled with the light pipe 508 of FIG. 5. In embodiments, the LDR module unit 614 may be included within the head unit 510 of FIG. 1.

In embodiments, the RMM 612 may be coupled with one or more servers 606a-606c, which may be similar to servers 106a-106c of FIG. 1. Each server 606a-606c may be associated respectively with a light source 606a1-606c1. Each light source 606a1-606c1 may be located within each server 606a-606c or may be coupled with each server 606a-606c. In embodiments, the light source 606a1-606c1 may be substantially adjacent to the server and may be to transmit light to the light pipe 508 of FIG. 5. In embodiments, the light source 606a1-606c1 may include light emitting diodes (LEDs).

In embodiments, to identify the location in a plurality of locations 104 in rack 102 of server 606b, the RMM 612 may send a command to a server 606b to turn on its light source 606b1. This may cause the light from the light source 606b1 to travel through the light pipe (not shown, but may be similar to light pipe 508 of FIG. 5) to the LDR module unit 614, which may measure the strength of the received light. This measured strength, together with the known strength of the initially transmitted light from the light source 606b1 and known characteristics of an opacity of the light pipe 508 per a unit of distance, may be used to calculate the distance of the light source 606b1 from the LDR module unit 614. As a result, a location of the server 606b within a plurality of locations 104 within the rack 102 may be determined.

In embodiments that may involve the detection of unique signals, each location of the plurality of server locations 104 may respectively have a light source (not shown) to transmit a light signal that may have a wavelength or some other unique detectable characteristic that is unique from any other light source within the rack 102. In embodiments, each wavelength may be associated with a particular location 104 within the rack 102.

For example, the RMM 612 may send a request to a server 606b to identify its location 104 within the server rack 602. In response to the request, the server 606b may turn on a light source adjacent to the server 606b on the light pipe (not shown, but may be similar to light pipe 508 of FIG. 5) that may transmit the unique light signal in the rack 102. In embodiments, LDR module 614, or some other appropriate sensor that may be located within the head unit (not shown, but may be similar to head unit 510 of FIG. 5), may receive or identify the unique wavelengths or other characteristic of the signal. The RMM 612 may receive this information and then may associate the one or more unique wavelengths with one or more locations within the rack 102. In embodiments, the RMM 612 may contain a table that may associate a signal wavelength or other characteristic with one of the plurality of locations 104 within the rack 102.

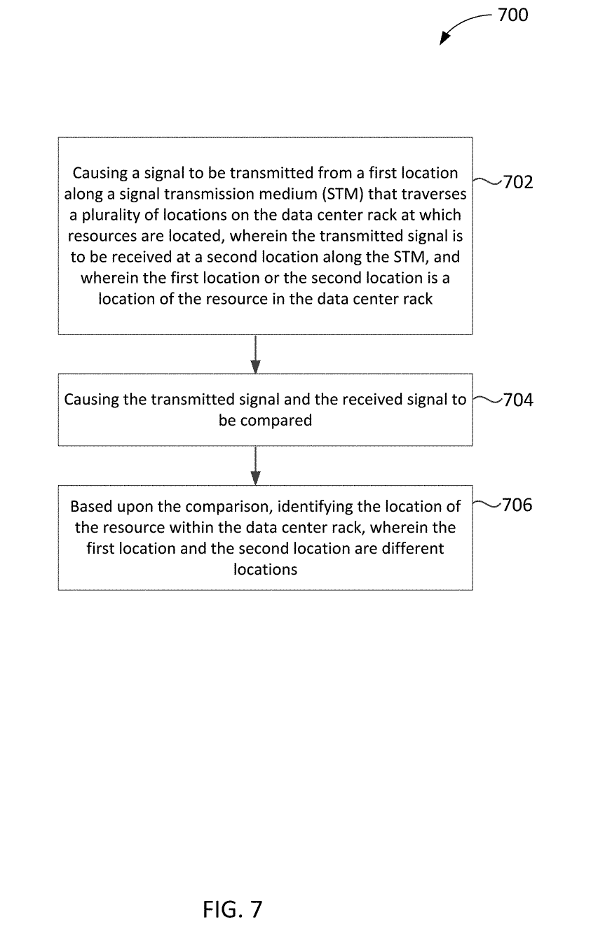

FIG. 7 is a block diagram that illustrates a process for using signal comparison to identify a location of a server within a data center rack, in accordance with various embodiments. In various embodiments, the RMM 512, head unit 510 of FIG. 5, and servers 506a-506c of FIG. 5, and RMM 612, LDR module unit 614, and servers 606c-606c of FIG. 6 may perform a portion of, or one or more of, the processes as described in diagram 700.

At block 702, the process may include causing a signal to be transmitted from a first location along an STM that traverses a plurality of locations on the data center rack at which resources are located, wherein the transmitted signal is to be received at a second location along the STM, and wherein the first location or the second location is a location of the resource in the data center rack. In embodiments where resources are servers, one of the servers 606a-606c, upon receiving the request from the RMM 512, may send or cause to send the signal onto the STM, such as light pipe 508 of FIG. 5, at a location that is substantially at the location of the one of the servers 606a-606c within the rack 102. In embodiments, the RMM 612 may transmit the request to send a signal to one of the servers 606a-606c. In embodiments the RMM 612 and the servers 606a-606c may be coupled by an Ethernet connection, a serial connection, a wireless connection, or some other connection by which the request may be addressed to and may reach one of the servers 606a-606c.

In embodiments the signal may be a light signal or wave with a known intensity or characteristics. The STM may be implemented as a light pipe, such as light pipe 508 of FIG. 5. In embodiments, the signal may be sent from the location of one of the servers 606a-606c to the head unit 510 that may detect the strength or some other characteristics of the light signal. In embodiments, the signal may be sent from the head unit 510 to one of the servers 606a-606c where characteristics of the received light signal may be determined by the server.

In embodiments, the signal may be an acoustical signal or wave with a known pitch, intensity, or other characteristics. Upon sending the acoustical signal on an STM, which may be similar to light pipe 508 of FIG. 5 that may be implemented as an acoustical pipe (not shown) or waveguide (not shown), the acoustical signal may travel through the STM and may reach a head unit 510 that may sense the pitch, intensity, or other characteristics of the acoustical signal.

In embodiments, the signal may be an electromagnetic signal or wave with a known wavelength, intensity, or other characteristics. Upon sending the signal on an STM that may be implemented as an electromagnetic waveguide (not shown) or similar medium to propagate an electromagnetic wave, the electromagnetic signal may travel through the STM and may reach a head unit 510 that may detect the wavelength, intensity, or other characteristics of the electromagnetic signal. In embodiments, other signals using other media within an STM for signal propagation may be used in a similar fashion.

In embodiments, the second location may be the head unit 510 of FIG. 5 that may be connected to or may be otherwise coupled to the STM, which may be similar to light pipe 508 of FIG. 5. In embodiments where the signal is a light signal, the second location may include an LDR, such as LDR 614 of FIG. 6, or a photo resistor, that may be located within the head unit 510, to sense the light signal. In embodiments where the signal may be an acoustical signal, the second location may be a location of a microphone or some other suitable listening device on the acoustical waveguide that may be similar to light pipe 508. In embodiments, the microphone may be located within the head unit 510. In embodiments where the signal is an electromagnetic signal, the second location may be an antenna (not shown) or other electromagnetic signal receiver, which may be located within the head unit 510.

In embodiments, the second location may be located at the end of the STM, which may be similar to light pipe 508, and may couple with the head unit 510. In embodiments, the second location may be located at a position along the STM 508 between the head unit 510 and the STM and opposite to the head unit 510.

At block 704, the process may include causing the transmitted signal and the received signal to be compared. In embodiments, this may include comparing one or more known or determined characteristics of a transmitted and received signal. These characteristics may include wavelength or amplitude. The signal may include a light signal, an acoustical signal, electromagnetic signal, or some other suitable signal.

At block 706, the process may include, based upon the comparison, identifying the location of the resource within the data center rack, wherein the first location and the second location are different locations. In embodiments where the signal is a light signal with a known intensity sent from a server at a first location, the comparison may include comparing the known intensity of the light at the first location with the received intensity of the light at the second location. In embodiments, the STM may be a light pipe and may have a known opacity of a distance along the STM. Based upon the difference in light intensity, a distance along the STM between the first location and the second location may be determined. In embodiments, this determined distance may be used to identify the location 104 of the server within the rack 102 that is at the first location that sent the light signal.

In embodiments, the signal from the server at the first location may have a wavelength or color that is unique to that first location. The location of the server may be determined based upon a comparison of the wavelength or color of the light signal received at the second location with known unique wavelength or color of light associated with each location 104. In embodiments, a list of various colors or wavelengths that are associated with each location within the plurality of locations 104 in the rack 102 may be stored within the RMM 512, or at some other location, and be used to identify the location based upon the wavelength or color of the light signal received at the second location.

In embodiments, the signal from the server at a first location may be an acoustical signal with a known volume or characteristic. In embodiments, the comparison may include comparing the known volume of the sound sent from the first location to the volume of the sound received at the second location. In embodiments, the light pipe 508 may be an acoustical waveguide with a known attenuation of sound per unit of distance along the acoustical waveguide, and based upon the difference in volume between the first location and the second location, a distance along the STM 508 may be determined. In embodiments, this determined distance may be used to identify the location of the server among the plurality of locations 104 within the rack 102 that may be at the first location that sent the sound.

In embodiments, the signal from the server at the first location may be an acoustical signal with a known pitch that is unique to that first location, and the location of the server may be determined based upon the pitch of the acoustical signal received at the second location. In embodiments, a list of various pitches that may be associated with each location within the plurality of locations 104 in the rack 102 may be stored within the RMM 512, or at some other location, and be used to identify the location based upon the acoustical signal pitch received at the second location.

In embodiments, the signal may be an electromagnetic signal sent from the server at a first location where the electromagnetic signal or wave has a known strength. In embodiments, the light pipe 508 may be an electromagnetic waveguide and the attenuation of an electromagnetic signal along a unit of distance of the electromagnetic waveguide is known. In embodiments, the comparison may include comparing the known strength of the electromagnetic signal sent from the first location to the strength of the electromagnetic signal received at the second location. In embodiments, based upon the attenuation of the electromagnetic signal, a distance along the electromagnetic waveguide, which may be similar to light pipe 508, between the first location and the second location may be determined. In embodiments, this determined distance may be used to identify the location of the server among the plurality of locations 104 within the rack 102 that may be at the first location that sent the electromagnetic signal.

In embodiments, the signal from the server at the first location may be an electromagnetic signal with a known frequency that may be unique to that first location, and the location of the server may be determined based upon the frequency of the electromagnetic signal received at the second location. In embodiments, a list of various frequencies that may be associated with each location within the plurality of locations 104 in the rack 102 may be stored within the RMM 512 and may be used to identify the location based upon the electromagnetic signal received at the second location.

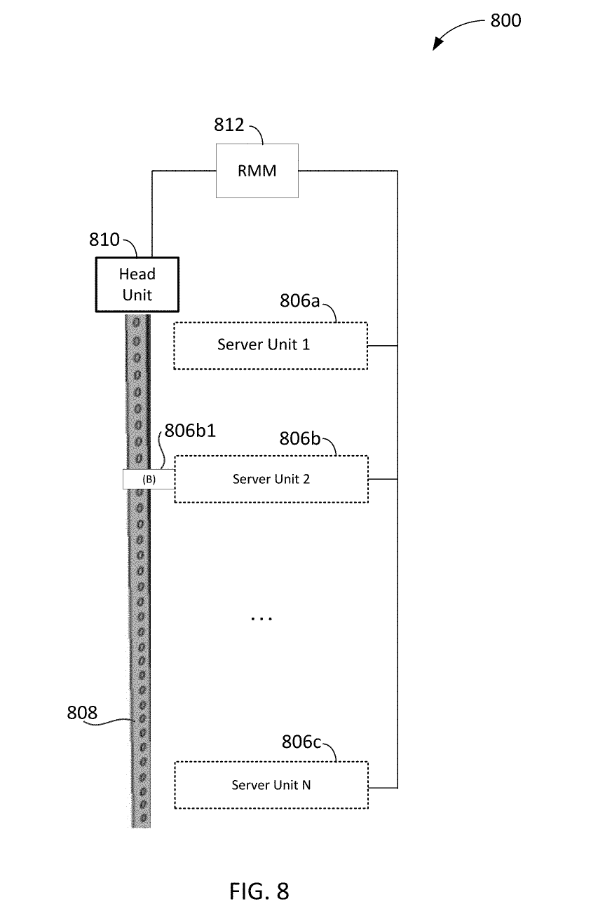

FIG. 8 is a diagram of a server reflecting a signal on an STM, in accordance with various embodiments. Diagram 800 shows an STM 808 that may be similar to STM 108 of FIG. 1. Servers 806a-806c, which may be similar to servers 106a-106c of FIG. 1, may be located respectively at various locations 104 within a rack 102 of FIG. 1. An RMM 812, which may be similar to RMM 112 of FIG. 1, may be coupled with the head unit 810, which may be similar to head unit 110 of FIG. 1, or may be coupled to the servers 806a-806c.

In embodiments, an STM 808 may allow a propagation of a signal that may include various types of signals waves through the STM 808. In embodiments, the various types of waves may include light waves, acoustical waves, electromagnetic waves, or some other suitable wave. In embodiments, the waves may also be signals. In embodiments, the STM 808 may be substantially orthogonal or substantially adjacent to the servers 806a-806c. In embodiments, the head unit 810 may generate the various types of waves and may direct the generated waves through the STM 808. In embodiments, the servers 806a-806c may generate the various types of waves. In embodiments, the STM 808 may be a pathway along which a wave or signal may travel.

In embodiments, servers 806a-806c may respectively include reflectors, for example, the reflector 806b1 of server 806b. In embodiments, a server 806b may deploy a reflector 806b1 to interact with the STM 808 in such a way as to reflect back a wave sent through the STM 808. For example, the reflector 806b1 may reflect a wave traveling along STM 808 that originated from a wave generation source within the head unit 810 back to the head unit 810. In embodiments, the signal may be generated elsewhere within the STM 808.

In embodiments, a reflector 806b1 may be a physical device or other object off of which a wave may bounce. For example, for a light signal, it may be a mirror, a white tag, or some other reflective surface. For electromagnetic or radio waves, the reflector 806b1 may be an object with conductive properties, for example, metal. For acoustic waves, a solid material may be used. In other embodiments, particularly with electromagnetic or radio waves, a reflector 806b1 may be a circuit that may be used to simulate a reflection by detecting an incoming wave and rebroadcasting it back in the opposite direction.

In embodiments, to locate the position of a server 806a-806c in the rack 102, the RMM 812 may send a command to a server 806b to deploy its reflector 806b1, and may send a command to the head unit 810 to send a wave down the STM 808. In embodiments, the head unit 810 may also include the ability to receive a reflected wave. In embodiments, the RMM 812, or some other device, may then determine, based upon the characteristics of the sent wave in comparison to the characteristics of the received reflected wave, the distance along the STM 808 between the head unit 810 and the location of the server 806b. From this determined distance, a specific location 104 of the server 806b within the rack 102 may be identified.

In embodiments, an STM 808 may not be a physical object but may be a pathway. In at least some of these embodiments, the wave generation source may have sufficient power or ability to focus the wave so that the wave reception resource, for example, within the head unit 810, may detect the characteristics of the received reflected wave from the reflector 806b1 attached to the server 806b.

In embodiments, the servers 806a-806c may have the ability to generate a wave and to detect a reflected wave, and a location along the STM 808, for example, at an end of the STM 808 at the head unit 810, may be a reflector.

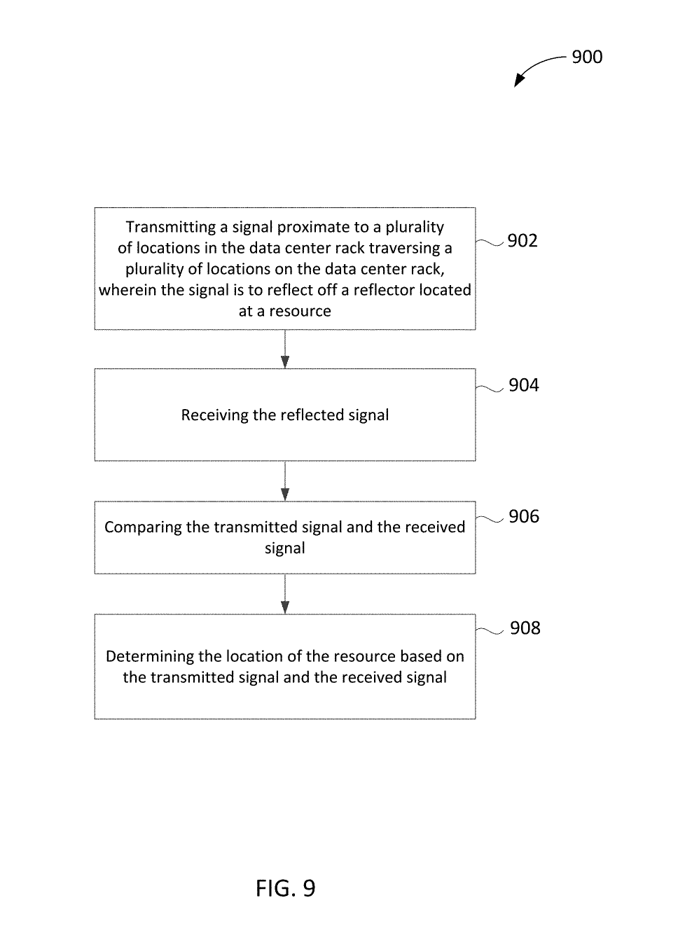

FIG. 9 is a block diagram that illustrates a process for using signal reflection to identify a location of a resource within a data center rack. In various embodiments, the RMM 812, head unit 810, and servers 806a-806c of FIG. 8 may perform a portion of, or one or more of, the processes as described in diagram 900.

At block 902, the process may include transmitting a signal proximate to a plurality of locations in the data center rack traversing a plurality of locations on the data center rack, wherein the signal is to reflect off a reflector located at a resource. In embodiments, the signal may be transmitted by a signal or wave generator that may be included within head unit 810. The signal may be an electromagnetic signal or wave, a light signal, or an acoustic signal. In embodiments, the RMM 812 may transmit a request to the head unit 810 to begin sending the signal. In embodiments, the RMM 812 may send a message through the network to one of a number of servers 806a-806c to deploy a reflector. In embodiments, a physical reflector 806b1 may be deployed by the server 806b. Examples of a physical reflector 806b1 may be described above.

At block 904, the process may include receiving the reflected signal. In embodiments, the reflected signal may be received by a signal or wave receiver or detector that may be included within the head unit 810.

At block 906, the process may include comparing the transmitted signal and the received signal. In embodiments, characteristics of the sent signal or wave and the received reflected signal or wave may be compared, and this comparison may be used to determine a distance between the signal or wave generator that may be included within head unit 810 and the location of the reflector that may be at substantially the same location as the server.

In embodiments, the comparing may include determining a shift in the signal phases that may be used to determine the distance described above. This and similar techniques may be suited to high-speed waves such as light waves or electromagnetic waves. In embodiments, the comparing may include measuring a delay in receiving the reflected wave. In embodiments, the delay may be used to determine the distance described above. This and similar techniques may be suited to lower speed waves such as sound waves. In embodiments, introducing a chirp or other discontinuity into the signal or wave may increase the precision of the measured distance.

At block 908, the process may include determining the location of the resource based on the transmitted signal and the received signal. In embodiments, once the distance described above has been determined, that distance may then be used to identify a specific location of the server 806b within the plurality of locations 104 of the rack 102. In embodiments, the RMM 812 may perform comparing the characteristics, determining the distance described above, or identifying the specific location of the server within the data center rack 802. In embodiments, some of this processing may be done by one of the servers 806b.

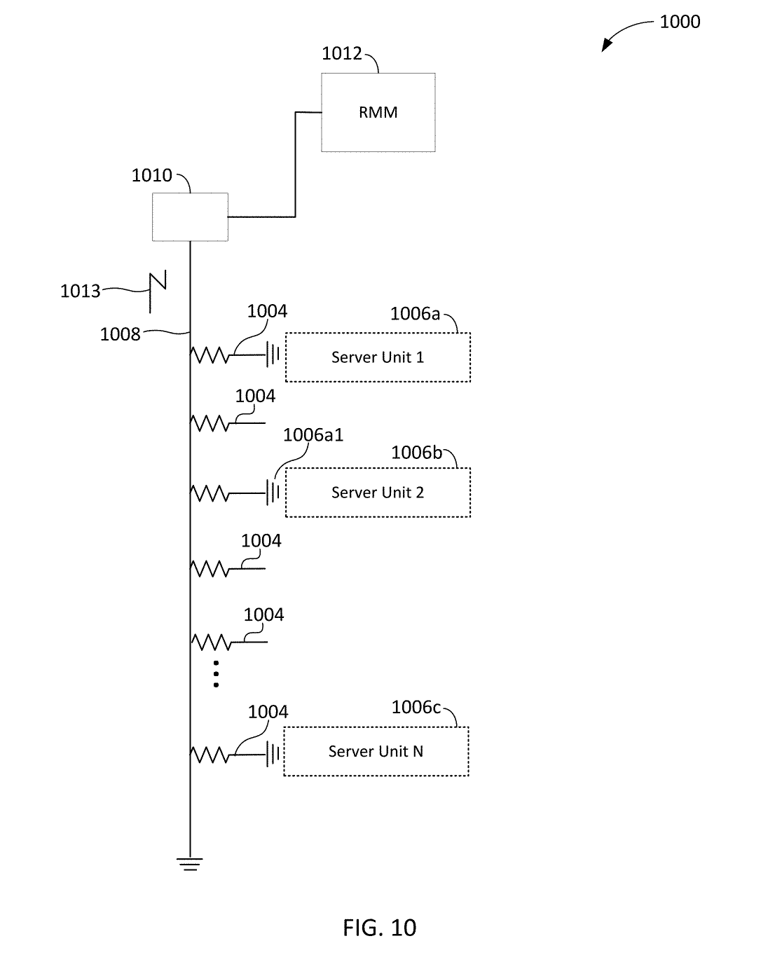

FIG. 10 is a diagram of a TDR to detect the presence or absence of resources within a data center rack, in accordance with various embodiments. Diagram 1000 shows servers 1006a-1006c, which may be similar to servers 106a-106c of FIG. 1, which may be in various locations within a plurality of locations 104 within a rack 102. A TDR 1010, which may be similar to the head unit 110 of FIG. 1, may be coupled with an RMM 1012, which may be similar to RMM 112 of FIG. 1.

In embodiments, a wire 1008, which may be similar to the STM 108 of FIG. 1, may have a plurality of potential connections 1004 at each location in the plurality of locations 104 in the rack 102 in which the servers 1006a-1006c may be located. In embodiments, when a server 1006a is located in one of the plurality of data center rack locations 104, the corresponding potential connection 1004 may be grounded 1006a1. In embodiments, if no server is located in one of the locations 104, the corresponding potential connection 1004 may be left open (not grounded).

In embodiments, the RMM 1012 may send a command to the TDR 1010 to send a shaped wave 1013 or electrical pulse along the wire 1008. In embodiments, the resulting wave, or reflection of that pulse, that may return to the TDR 1010 may indicate which of the plurality of potential connections 1004 are at ground and therefore may include an installed server 1006a-1006c. In embodiments, data from the resulting wave received by the TDR 1010 may be transmitted to the RMM 1012 for further processing, for example, identifying which of the plurality of locations 104 include a server 1006a-1006c.

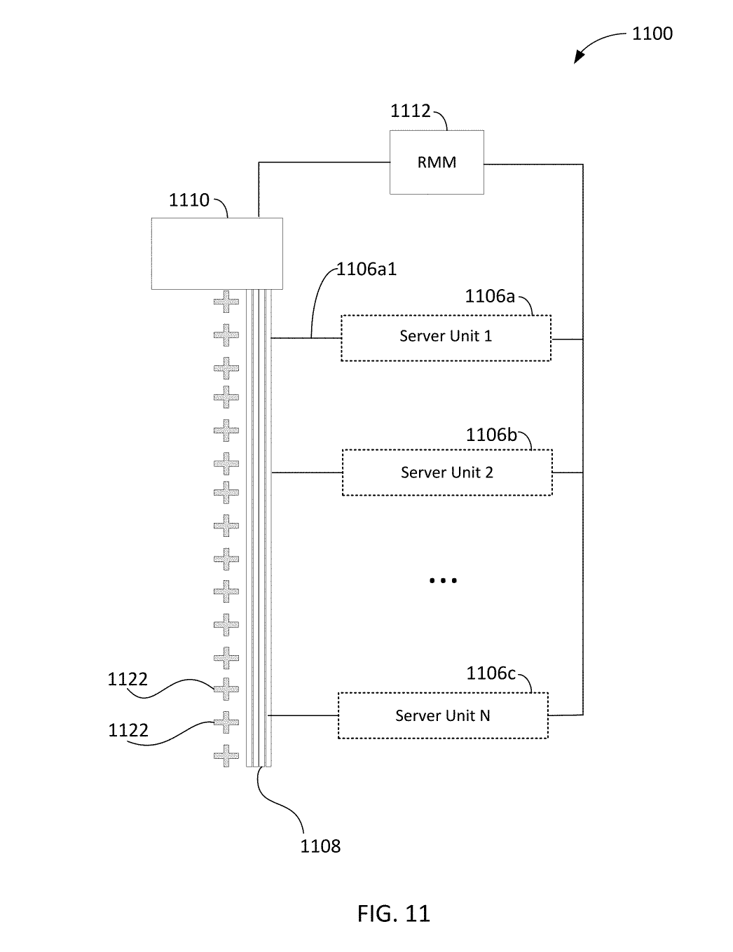

FIG. 11 is a block diagram that illustrates an STM as a digital bus with data modifiers, in accordance with various embodiments. In embodiments, the data modifier 1122 may be an adder, subtractor, bit shifter, or other circuit that may change a data signal data value. Diagram 1100 shows servers 1106a-1106c, which may be similar to servers 106a-106c of FIG. 1 that may be located respectively in various locations 104 within a rack 102. A head unit 1110, which may be similar to head unit 110 of FIG. 1, may be coupled with a data bus 1108, which may be similar to STM 108 of FIG. 1. In embodiments, the data bus 1108 may allow data on the bus to be read from each location of the plurality of locations 104 within the rack 102 by a server 1106a installed in a location.

In embodiments, the data bus 1108 may couple a plurality of data modifiers 1122. In embodiments, the plurality of data modifiers 1122 may correspond with the number of the plurality of locations 104 within a rack 102. In embodiments, the data modifiers 1122 may be located along the bus 1108 such that one data modifier 1122 may be located between each of the plurality of locations 104.

In embodiments, the head unit 1110 may propagate a signal having an initial data value onto the bus 1108, with each data modifier 1122 adding an incremental value to the data value it receives as the signal is propagated down the bus 1108. For example, the initial data value may be zero, with each data modifier 1122 adding a value of one, so that the data value of a segment of the bus 1108 may be one greater than the segment before it and one less than the segment after it.

In another embodiment, the RMM 1112 may send a request to a server 1106b to send a data signal, for example, 0 or 1, on the bus 1108 through each data modifier 1122 as the data signal moves toward the head unit 1110. The value of the data signal may then be read by the head unit 1110 and determine the location of the server 1106b.

In embodiments, the data value on a segment of the bus 1108 between data modifiers 1122 may be read by a server 1106a using a coupling 1106a1 to the bus 1108. Based upon the read data value, the location of the server 1106a may be determined. In embodiments, the data value may correspond to a U position within the rack 102 and hence a location of the server 1106a. In embodiments, a formula applied to the data value may determine the location, or some other mapping may be used to determine the location within the rack 102.

In embodiments, the bus 1108 may be a single wire able to transmit digital data values, or may include a bundle of wires, each representing one bit of a data value.

In embodiments, the data modifier 1122 may be a bit shifter that shifts the input bit vector by one bit left or right. When head unit 1110 propagates a value of binary 1, each bit shifter 1122 may shift the bit to the left. The value read by the server unit 1106a may indicate the number of bits shifted and determine the location of the server position within the data center rack.

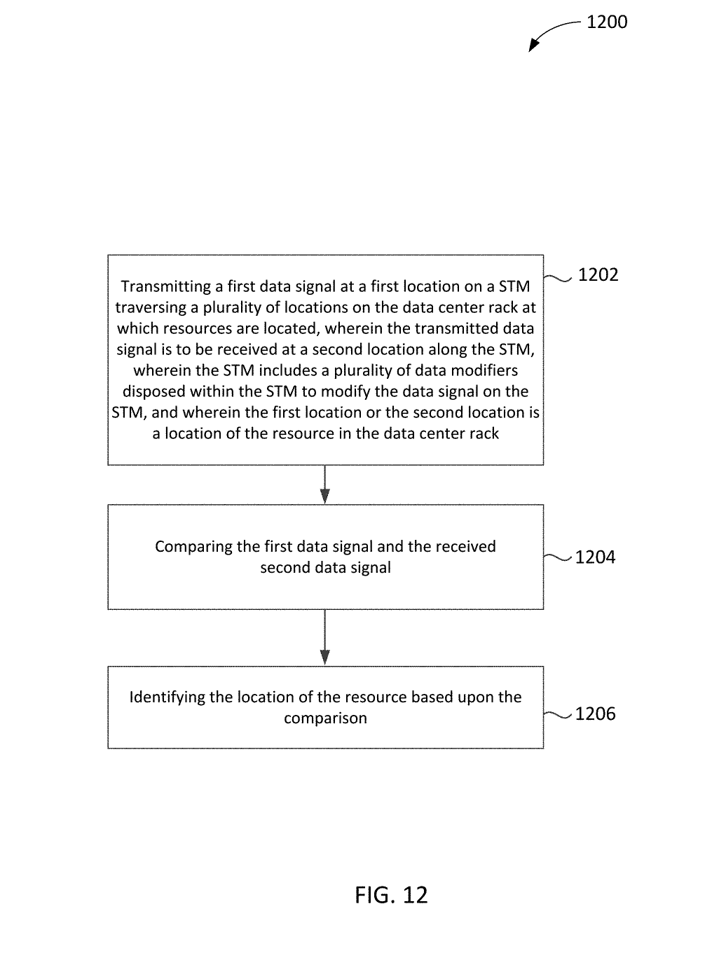

FIG. 12 is a block diagram that illustrates a process for using data modifiers to identify a location of a resource within a data center rack, in accordance with various embodiments. In various embodiments, the RMM 1112, head unit 1110, and servers 1106a-1106c of FIG. 11 may perform a portion of, or one or more of, the processes as described in diagram 1200.

At block 1202, the process may include transmitting a first data signal at a first location on an STM traversing a plurality of locations on the data center rack at which resources are located, wherein the transmitted data signal is to be received at a second location along the STM, wherein the STM includes a plurality of data modifiers disposed within the STM to modify the data signal on the STM, and wherein the first location or the second location is a location of the resource in the data center rack. In embodiments, RMM 1112 may send a request to the head unit 1110 to send a first data signal on the STM, which may be implemented as data bus 1108. In embodiments, the RMM 1112 may have received a request to do so from one of the server units 1106a-1106c. In embodiments, the first data signal may include a first data value. The first location or the second location may be located at an end of the data bus 1108, for example, at head unit 1110, may be located at the resource, which may be a server 1106a, or may be located at some other location along the data bus 1108.

In embodiments, the plurality of data modifiers 1122 may modify the data value of the first data signal as the signal propagates down the bus 1108. In embodiments, data modifiers 1122 may include adders, subtractors, or bit shifters. In embodiments, a resource such as server 1106a may read the second data signal on the bus 1108 using a coupling 1106a1. In embodiments, the second data signal may include a second data value.

At block 1204, the process may include comparing the first data signal and the received second data signal. In embodiments, a comparison between the first data value from the first data signal and the second data value from the second data signal may be used to determine how many data modifiers 1122 the signal has encountered before reaching the location of the server 1006a within the plurality of locations 104 of rack 102.

At block 1206, the process may include identifying the location of the resource based upon the comparison. In embodiments, where the first data value is zero and the data modifiers 1122 are spaced at each U location within the data center rack 102, the second data value may indicate the U location within the data center rack 102 at which the server 1006a may be located. In embodiments, the difference between the first data value and the second data value may indicate a specific location 104.

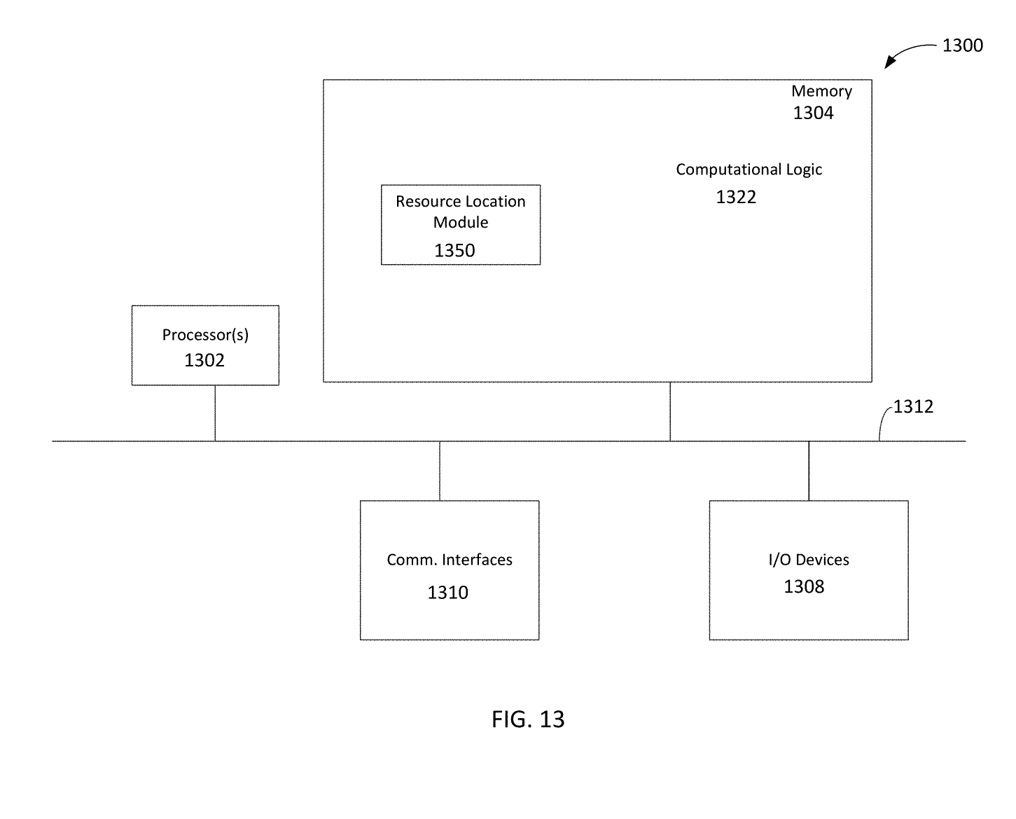

FIG. 13 illustrates an example computing device 1300 suitable for use to practice aspects of the present disclosure, in accordance with various embodiments. For example, the example computing device 1300 may be suitable to implement the functionalities associated with diagrams 100, 200, 300, 400, 500, 600, 700, 800, 900, 1000, 1100, and 1200. As shown, computing device 1300 may include one or more processors 1302, each having one or more processor cores, and system memory 1304.

The processor 1302 may include any type of unicore or multi-core processors. Each processor core may include a central processing unit (CPU), and one or more level of caches. The processor 1302 may be implemented as an integrated circuit. The computing device 1300 may include mass storage devices (not shown) such as diskette, hard drive, or volatile memory (e.g., dynamic random access memory (DRAM)), compact disc read only memory (CD-ROM), digital versatile disk (DVD) and so forth.

The computing device 1300 may further include input/output (I/O) devices 1308 such as a display, keyboard, cursor control, remote control, gaming controller, image capture device, one or more three-dimensional cameras used to capture images, and so forth, and communication interfaces 1310 (such as network interface cards, modems, infrared receivers, transceivers, radio receivers (e.g., Bluetooth), and so forth). I/O devices 1308 may be suitable for communicative connections with servers such as servers 106a-106c of FIG. 1 that are located in rack 102, head units such as head unit 110 of FIG. 1, or other devices that may be used for implementing the functionalities of determining the location or a server in a rack having a plurality of locations, as described in reference to FIGS. 1-12.

The communication interfaces 1310 may include communication chips (not shown) that may be configured to operate the device 1300 in accordance with wired or with wireless protocols in other embodiments.

The above-described computing device 1300 elements may be coupled to each other via system bus 1312, which may represent one or more buses. In the case of multiple buses, they may be bridged by one or more bus bridges (not shown). Each of these elements may perform its conventional functions known in the art. In particular, system memory 1304 and mass storage devices (not shown) may be employed to store a working copy and a permanent copy of the programming instructions implementing the operations and functionalities associated with the RMM such as RMM 112 of FIG. 1, generally shown as computational logic 1322. Computational logic 1322 may be implemented by assembler instructions supported by processor(s) 1302 or high-level languages that may be compiled into such instructions.

In embodiments, the computational logic 1322 may contain a resource location module 1350, which may perform one or more of the functions associated with diagrams 100, 200, 300, 400, 500, 600, 700, 800, 900, 1000, 1100, and 1200.

The permanent copy of the programming instructions may be placed into mass storage devices (not shown) in the factory, or in the field, through, for example, a distribution medium (not shown), such as a compact disc (CD), or through communication interfaces 1310 (from a distribution server (not shown)).

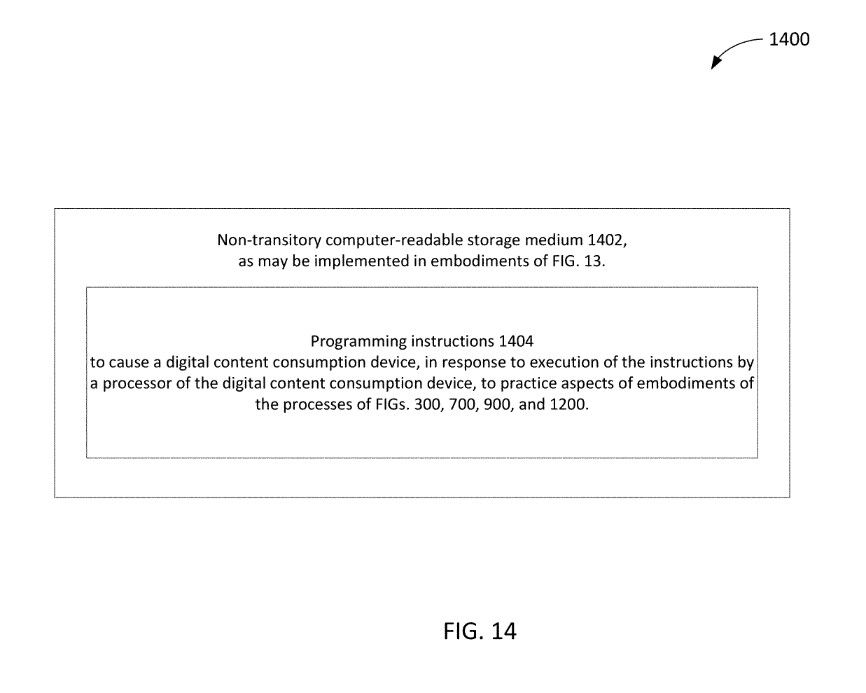

FIG. 14 is a diagram illustrating computer-readable media having instructions for practicing the above-describe techniques, or for programming/causing systems and devices to perform the above-describe techniques, in accordance with various embodiments. In various embodiments, such computer-readable media 1402 may be included in a memory or storage device, which may be transitory or non-transitory, of the RMM such as the RMM 112 of FIG. 1. In embodiments, instructions 1404 may include assembler instructions supported by a processing device, or may include instructions in a high-level language, such as C, that can be compiled into object code executable by the processing device. In some embodiments, a persistent copy of the computer-readable instructions 1404 may be placed into a persistent storage device in the factory or in the field (through, for example, a machine-accessible distribution medium (not shown)). In various embodiments, a persistent copy of the computer-readable instructions 1404 may be placed into a persistent storage device through a suitable communication pathway (e.g., from a distribution server).

The corresponding structures, material, acts, and equivalents of all means or steps plus function elements in the claims below are intended to include any structure, material or act for performing the function in combination with other claimed elements that are specifically claimed. The description of the present disclosure has been presented for purposes of illustration and description, but is not intended to be exhaustive or limited to the disclosure in the form disclosed. Many modifications and variations will be apparent to those of ordinary skill without departing from the scope and spirit of the disclosure. The embodiment was chosen and described in order to best explain the principles of the disclosure and the practical application, and to enable others of ordinary skill in the art to understand the disclosure for embodiments with various modifications as are suited to the particular use contemplated.

### EXAMPLES

Examples, according to various embodiments, may include the following.

Example 1 may be an apparatus to identify a location of a resource among a plurality of locations in a rack, comprising: one or more processors; and a resource location module to operate on the processors to: cause a voltage to be applied at a first location along a resistive wire with a known resistance per length of the resistive wire that traverses a plurality of locations on the rack at which resources are located; measure a voltage at a second location along the resistive wire; and cause characteristics of the voltage applied at the first location and characteristics of the voltage measured at the second location to be compared; wherein based upon the comparison, a location of the resource within the rack is identified; and wherein the first location or the second location is the location of the resource in the rack.

Example 2 may include the apparatus of example 1, wherein the first location is an end of the resistive wire and the second location is the location of the resource in the rack; and wherein to cause a voltage to be applied at a first location further comprises to cause a switch to be closed to connect a voltage source with the resistive wire at the first location.

Example 3 may include the apparatus of example 2, wherein the switch and the resource location module are coupled.

Example 4 may include the apparatus of example 1, wherein to cause a voltage to be applied at a first location further comprises to cause a resource located in the rack to apply the voltage at the first location.

Example 5 may include the apparatus of any one of examples 1-4, wherein the apparatus is included within a resource management module (RMM) or within a resource located in the rack.

Example 6 may include the apparatus of any one of examples 1-4, wherein the resistive wire is a high resistance wire or carbon resistor ignition cable with resistance properties measured in ohms per foot.

Example 7 may include the apparatus of any one of examples 1-4, wherein the resistive wire is a wire with resistors placed evenly along the wire.

Example 8 may include the apparatus of any one of examples 1-4, wherein the resistive wire is a wire with resistors placed at each U position within the rack.

Example 9 may be an apparatus to identify a location of a resource among a plurality of locations in a rack, comprising: one or more processors; and a resource location module to operate on the processors to: cause a current to be applied by a resource at a location along a resistive wire with a known resistance per length of the resistive wire that traverses a plurality of locations on the rack at which resources are located with one end of the resistive wire connected to ground; and cause a voltage to be measured at the location; wherein based upon the measured voltage, the location of the resource within the rack is identified.

Example 10 may include the apparatus of example 9, wherein the apparatus is included within a resource management module (RMM) or within a resource located in the rack.

Example 11 may include the apparatus of example 9, wherein the resistive wire is a high resistance wire or carbon resistor ignition cable with resistance properties measured in ohms per foot.

Example 12 may include the apparatus of example 9, wherein the resistive wire is a wire with resistors placed evenly along the wire.

Example 13 may include the apparatus of example 9, wherein the resistive wire is a wire with resistors placed at each U position within the rack.

Example 14 may be an apparatus to identify a location of a resource among a plurality of locations in a rack, comprising: one or more processors; and a resource location module to operate on the processors to: cause a light to enter a first location along a light pipe that traverses a plurality of locations on the rack at which resources are located; cause light to be received at a second location along the light pipe; and cause characteristics of the light at the first location and characteristics of the light at the second location to be compared; wherein based upon the comparison, a location of the resource within the rack is identified; and wherein the first location or the second location is the location of the resource in the rack.

Example 15 may include the apparatus of example 14, wherein the light pipe attenuates light by a determined amount over a known distance of the light pipe; and wherein the comparison further includes to compare an intensity of the light at the first location with an intensity of light at the second location.

Example 16 may include the apparatus of any one of examples 14-15, wherein the first location along the light pipe is an end of the light pipe and the second location along the light pipe is at the location of the resource.

Example 17 may include the apparatus of any one of examples 14-15, wherein the first location along the light pipe is at the location of the resource and the second location along the light pipe is at an end of the light pipe.

Example 18 may be an apparatus to identify a location of a resource among a plurality of locations in a rack, comprising: one or more processors; and a resource location module to operate on the processors to: cause a light to enter a first location of a resource within a rack along a light pipe that traverses a plurality of locations on the rack at which resources are located; and cause a wavelength of the light to be identified at a second location along the light pipe; wherein based upon the identified wavelength, a location of the resource within the rack is identified.

Example 19 may include the apparatus of example 18, wherein the first location along the light pipe is an end of the light pipe and the second location along the light pipe is at the location of the resource.

Example 20 may include the apparatus of example 18, wherein the first location along the light pipe is at the location of the resource and the second location along the light pipe is at an end of the light pipe.

Example 21 may be an apparatus to identify a location of a resource among a plurality of locations in a rack, comprising: one or more processors; and a resource location module to operate on the processors to: cause an audio signal to be transmitted at a first location along an acoustical waveguide that traverses a plurality of locations on the rack at which resources are located; deploy, at a second location, a reflector to reflect the audio signal back along the acoustical waveguide to be received at the first location; and cause characteristics of the audio signal as transmitted and the audio signal as received to be compared; wherein based upon the comparison, a location of the resource within the rack is identified.

Example 22 may include the apparatus of example 21, wherein the first location along the acoustical waveguide is an end of the light pipe and the second location along the acoustical waveguide is at the location of the resource.

Example 23 may include the apparatus of example 21, wherein the first location along the acoustical waveguide is at the location of the resource and the second location along the acoustical waveguide is at an end of the light pipe.

Example 24 may be an apparatus to identify a location of a resource among a plurality of locations in a rack, comprising: one or more processors; and a resource location module to operate on the processors to: cause an audio signal to be transmitted at a first location along an acoustical waveguide that traverses a plurality of locations on the rack at which resources are located, wherein the acoustical waveguide is to attenuate the audio signal by a determined amount over a known distance of the acoustical waveguide; receive, at a second location along the acoustical waveguide, an audio signal; and cause characteristics of the audio signal as transmitted and the audio signal as received to be compared; wherein based upon the comparison, a location of the resource within the rack is identified and wherein the first location or the second location is the location of the resource in the rack.

Example 25 may include the apparatus of example 24, wherein the first location along the acoustical waveguide is an end of the acoustical waveguide and the second location along the acoustical waveguide is at the location of the resource.

Example 26 may include the apparatus of example 24, wherein the first location along the acoustical waveguide is at the location of the resource and the second location along the acoustical waveguide is at an end of the acoustical waveguide.

Example 27 may be an apparatus to identify a location of a resource among a plurality of locations in a rack, comprising: one or more processors; and a resource location module to operate on the processors to: cause an audio signal to be transmitted at a first location of a resource within a rack along an acoustical waveguide that traverses a plurality of locations on the rack at which resources are located; and cause a wavelength of the audio signal to be identified at a second location along the acoustical waveguide; wherein based upon the identified wavelength, a location of the resource within the rack is identified and wherein the first location or the second location is the location of the resource in the rack.

Example 28 may include the apparatus of example 27, wherein the first location along the acoustical waveguide is an end of the acoustical waveguide and the second location along the acoustical waveguide is at the location of the resource.

Example 29 may include the apparatus of example 27, wherein the first location along the acoustical waveguide is at the location of the resource and the second location along the acoustical waveguide is at an end of the acoustical waveguide.

Example 30 may be an apparatus to identify a location of a resource among a plurality of locations in a rack, comprising: one or more processors; and a resource location module to operate on the processors to: cause an electromagnetic signal to be transmitted at a first location along an electromagnetic waveguide that traverses a plurality of locations on the rack at which resources are located; and cause characteristics of the electromagnetic signal to be identified at a second location along the electromagnetic waveguide; wherein based upon the identified characteristics, a location of the resource within the rack is identified; and wherein the first location or the second location is the location of the resource in the rack.

Example 31 may include the apparatus of example 30, wherein the electromagnetic waveguide is to attenuate the electromagnetic signal by a determined amount over a known distance of the electromagnetic waveguide.

Example 32 may include the apparatus of example 30, wherein one of the identified characteristics of the electromagnetic signal is a wavelength.

Example 33 may include the apparatus of any one of examples 30-32, wherein the first location along the electromagnetic waveguide is an end of the electromagnetic waveguide and the second location along the electromagnetic waveguide is at the location of the resource.

Example 34 may include the apparatus of any one of examples 30-32, wherein the first location along the electromagnetic waveguide is at the location of the resource and the second location along the electromagnetic waveguide is at an end of the electromagnetic waveguide.

Example 35 may be an apparatus to identify a location of a resource among a plurality of locations in a rack, comprising: one or more processors; and a resource location module to operate on the processors to: cause a data value to be transmitted at a first location along a data bus with one or more data modifiers located on the data bus at regular intervals that traverses a plurality of locations on the rack at which resources are located; cause a data value to be identified at a second location along the data bus; and cause the data value at the first location and the data value at the second location to be compared; wherein based upon the comparison, a location of the resource within the rack is identified; and wherein the first location or the second location is the location of the resource in the rack.

Example 36 may include the apparatus of example 35, wherein the first location is at an end of the data bus and the second location is at the location of the resource.

Example 37 may include the apparatus of example 35, wherein the first location is at the location of the resource and the second location is at an end of the data bus.

Example 38 may include the apparatus of any one of examples 35-37, wherein the data modifier is an adder, a subtractor or a bit shifter.

Example 39 may include the apparatus of example 38, wherein the data modifiers are located on the data bus at each U position of the rack.

Example 40 may be an apparatus for identifying a location of a resource among a plurality of locations in a rack, comprising: one or more processors; a resource location module to operate on the processors to: cause a signal to be transmitted from a first location on a path that traverses a plurality of locations on the rack at which resources may be located, to a signal reflector at a second location, wherein the reflected signal is to be received at the first location; and cause characteristics of the signal as transmitted and as received after reflection to be compared; wherein based upon the comparison, the location of the resource within the rack is identified.

Example 41 may include the apparatus of example 40, wherein the transmitted signal and the reflected signal travel on a signal transmission medium (STM).

Example 42 may include the apparatus of example 40, wherein the first location is a location of the resource in the rack and the signal reflector is at a known location proximate to the rack.

Example 43 may include the apparatus of example 40, wherein the first location is a known location proximate to the rack; and wherein the signal reflector is coupled to the resource.

Example 44 may include the apparatus of example 43, wherein the resource location module is further to cause the signal reflector to physically deploy from the resource to reflect the transmitted signal back to the first location.

Example 45 may include the apparatus of any one of examples 40-44, wherein cause characteristics of the signal as transmitted and the signal as received after reflection to be compared further includes to cause a phase of the transmitted signal and a phase of the signal as received after reflection to be compared.

Example 46 may include the apparatus of any one of examples 40-44, wherein the signal as transmitted and the signal as received after reflection are light signals, acoustical signals, or electromagnetic signals.

Example 47 may be an apparatus to identify resources among a plurality of locations in a rack, comprising: one or more processors; and a resource location module to operate on the processors to: cause a time domain reflectometer (TDR) signal to be transmitted from a first location along an electrically conductive wire that traverses a plurality of locations in the rack at which resources may be located, the conductive wire having electrical connections respectively at each of the plurality of locations; wherein a plurality of locations along the wire where a resource is located have electrical connections that are grounded; wherein a plurality of locations along the wire where a resource is not located have electrical connections that are open; receive a reflection of the TDR signal at the first location; and based upon the received reflection of the TDR signal, determine a subset of the plurality of locations in the rack at which resources are located.

Example 48 may include the apparatus of example 47, wherein the TDR signal is a shaped electrical wave or an electrical pulse.

Example 49 may be a method to identify a location of a resource among a plurality of locations in a rack, comprising: causing a voltage to be applied at a first location along a resistive wire with a known resistance per length of the resistive wire that traverses a plurality of locations on the rack at which resources are located; measuring a voltage at a second location along the resistive wire; and causing characteristics of the voltage applied at the first location and characteristics of the voltage measured at the second location to be compared; wherein based upon the comparison, a location of the resource within the rack is identified; and wherein the first location or the second location is the location of the resource in the rack.

Example 50 may include the subject matter of example 49, wherein the first location is an end of the resistive wire and the second location is the location of the resource in the rack; and wherein causing a voltage to be applied at a first location further comprises causing a switch to be closed to connect a voltage source with the resistive wire at the first location.

Example 51 may include the subject matter of example 50, wherein the switch and the resource location module are coupled.

Example 52 may include the subject matter of example 49, wherein causing a voltage to be applied at a first location further comprises causing a resource located in the rack to apply the voltage at the first location.

Example 53 may include the subject matter of any one of examples 49-52, wherein the resistive wire is a high resistance wire or carbon resistor ignition cable with resistance properties measured in ohms per foot.

Example 54 may include the subject matter of any one of examples 49-52, wherein the resistive wire is a wire with resistors placed evenly along the wire.

Example 55 may include the subject matter of any one of examples 49-52, wherein the resistive wire is a wire with resistors placed at each U position within the rack.

Example 56 may be a method to identify a location of a resource among a plurality of locations in a rack, comprising: causing a current to be applied by a resource at a location along a resistive wire with a known resistance per length of the resistive wire that traverses a plurality of locations on the rack at which resources are located with one end of the resistive wire connected to ground; and causing a voltage to be measured at the location; and identifying, based upon the measured voltage, the location of the resource within the rack.

Example 57 may include the subject matter of example 56, wherein the resistive wire is a high resistance wire or carbon resistor ignition cable with resistance properties measured in ohms per foot.

Example 58 may include the subject matter of example 56, wherein the resistive wire is a wire with resistors placed evenly along the wire.

Example 59 may include the subject matter of example 56, wherein the resistive wire is a wire with resistors placed at each U position within the rack.

Example 60 may be a method to identify a location of a resource among a plurality of locations in a rack, comprising: causing a light to enter a first location along a light pipe that traverses a plurality of locations on the rack at which resources are located; receiving light at a second location along the light pipe; and comparing characteristics of the light at the first location and characteristics of the light at the second location; based upon the comparison, identifying a location of the resource within the rack is identified; and wherein the first location or the second location is the location of the resource in the rack.

Example 61 may include the subject matter of example 60, wherein the light pipe attenuates light by a determined amount over a known distance of the light pipe; and wherein comparing further includes comparing an intensity of the light at the first location with an intensity of light at the second location.

Example 62 may include the subject any matter of examples 60-61, wherein the first location along the light pipe is an end of the light pipe and the second location along the light pipe is at the location of the resource.

Example 63 may include the subject matter of any one of examples 60-61, wherein the first location along the light pipe is at the location of the resource and the second location along the light pipe is at an end of the light pipe.

Example 64 may be a method to identify a location of a resource among a plurality of locations in a rack, comprising: causing a light to enter a first location of a resource within a rack along a light pipe that traverses a plurality of locations on the rack at which resources are located; and identifying a wavelength of the light at a second location along the light pipe; determining, based upon the identified wavelength, a location of the resource within the rack.

Example 65 may include the subject matter of example 64, wherein the first location along the light pipe is an end of the light pipe and the second location along the light pipe is at the location of the resource.

Example 66 may include the subject matter of example 64, wherein the first location along the light pipe is at the location of the resource and the second location along the light pipe is at an end of the light pipe.

Example 67 may be a method to identify a location of a resource among a plurality of locations in a rack, comprising: causing an audio signal to be transmitted at a first location along an acoustical waveguide that traverses a plurality of locations on the rack at which resources are located; deploying at a second location, a reflector to reflect the audio signal back along the acoustical waveguide to be received at the first location; and causing characteristics of the audio signal as transmitted and the audio signal as received to be compared; determining, based upon the comparison, a location of the resource within the rack.

Example 68 may include the subject matter of example 67, wherein the first location along the acoustical waveguide is an end of the light pipe and the second location along the acoustical waveguide is at the location of the resource.

Example 69 may include the subject matter of example 67, wherein the first location along the acoustical waveguide is at the location of the resource and the second location along the acoustical waveguide is at an end of the light pipe.

Example 70 may be a method to identify a location of a resource among a plurality of locations in a rack, comprising: causing an audio signal to be transmitted at a first location along an acoustical waveguide that traverses a plurality of locations on the rack at which resources are located, wherein the acoustical waveguide is to attenuate the audio signal by a determined amount over a known distance of the acoustical waveguide; receiving at a second location along the acoustical waveguide, an audio signal; and comparing characteristics of the audio signal as transmitted and the audio signal as received; identifying, based upon the comparison, a location of the resource within the rack; and wherein the first location or the second location is the location of the resource in the rack.

Example 71 may include the subject matter of example 70, wherein the first location along the acoustical waveguide is an end of the acoustical waveguide and the second location along the acoustical waveguide is at the location of the resource.

Example 72 may include the subject matter of example 70, wherein the first location along the acoustical waveguide is at the location of the resource and the second location along the acoustical waveguide is at an end of the acoustical waveguide.

Example 73 may be a method to identify a location of a resource among a plurality of locations in a rack, comprising: causing an audio signal to be transmitted at a first location of a resource within a rack along an acoustical waveguide that traverses a plurality of locations on the rack at which resources are located; and identifying a wavelength of the audio signal at a second location along the acoustical waveguide; wherein based upon the identified wavelength, a location of the resource within the rack is identified and wherein the first location or the second location is the location of the resource in the rack.

Example 74 may include the subject matter of example 73, wherein the first location along the acoustical waveguide is an end of the acoustical waveguide and the second location along the acoustical waveguide is at the location of the resource.

Example 75 may include the subject matter of example 73, wherein the first location along the acoustical waveguide is at the location of the resource and the second location along the acoustical waveguide is at an end of the acoustical waveguide.

Example may be a method to identify a location of a resource among a plurality of locations in a rack, comprising: causing an electromagnetic signal to be transmitted at a first location along an electromagnetic waveguide that traverses a plurality of locations on the rack at which resources are located; and causing characteristics of the electromagnetic signal to be identified at a second location along the electromagnetic waveguide; wherein based upon the identified characteristics, a location of the resource within the rack is identified; and wherein the first location or the second location is the location of the resource in the rack.

Example 77 may include the subject matter of example 76, wherein the electromagnetic waveguide is to attenuate the electromagnetic signal by a determined amount over a known distance of the electromagnetic waveguide.

Example 78 may include the subject matter of example 76, wherein one of the identified characteristics of the electromagnetic signal is a wavelength.

Example 79 may include the subject matter of any one of examples 76-78, wherein the first location along the electromagnetic waveguide is an end of the electromagnetic waveguide and the second location along the electromagnetic waveguide is at the location of the resource.

Example 80 may include the subject matter of any one of examples 76-78, wherein the first location along the electromagnetic waveguide is at the location of the resource and the second location along the electromagnetic waveguide is at an end of the electromagnetic waveguide.

Example 81 may be a method to identify a location of a resource among a plurality of locations in a rack, comprising: causing a data value to be transmitted at a first location along a data bus with one or more data modifiers located on the data bus at regular intervals that traverses a plurality of locations on the rack at which resources are located; causing a data value to be identified at a second location along the data bus; and comparing the data value at the first location and the data value at the second; wherein based upon the comparison, a location of the resource within the rack is identified; and wherein the first location or the second location is the location of the resource in the rack.

Example 82 may include the subject matter of example 81, wherein the first location is at an end of the data bus and the second location is at the location of the resource.

Example 83 may include the subject matter of example 81, wherein the first location is at the location of the resource and the second location is at an end of the data bus.

Example 84 may include the subject matter of any one of examples 81-83, wherein the data modifier is an adder, a subtractor or a bit shifter.

Example 85 may include the subject matter of example 84, wherein the data modifiers are located on the data bus at each U position of the rack.

Example 86 may be a method for identifying a location of a resource among a plurality of locations in a rack, comprising: causing a signal to be transmitted from a first location on a path that traverses a plurality of locations on the rack at which resources may be located, to a signal reflector at a second location, wherein the reflected signal is to be received at the first location; and comparing characteristics of the signal as transmitted and as received after reflection; wherein based upon the comparison, the location of the resource within the rack is identified.

Example 87 may include the subject matter of example 86, wherein the transmitted signal and the reflected signal travel on a signal transmission medium (STM).

Example 88 may include the subject matter of example 86, wherein the first location is a location of the resource in the rack and the signal reflector is at a known location proximate to the rack.

Example 89 may include the subject matter of example 86, wherein the first location is a known location proximate to the rack; and wherein the signal reflector is coupled to the resource.

Example 90 may include the subject matter of example 89, further comprising causing the signal reflector to physically deploy from the resource to reflect the transmitted signal back to the first location.

Example 91 may include the subject matter of any one of examples 86-90, wherein comparing characteristics of the signal as transmitted and the signal as received after reflection further includes comparing a phase of the transmitted signal and a phase of the signal as received.

Example 92 may include the subject matter of any one of examples 86-90, wherein the signal as transmitted and the signal as received after reflection are light signals, acoustical signals, or electromagnetic signals.

Example 93 may be a method to identify resources among a plurality of locations in a rack, comprising: causing a time domain reflectometer (TDR) signal to be transmitted from a first location along an electrically conductive wire that traverses a plurality of locations in the rack at which resources may be located, the conductive wire having electrical connections respectively at each of the plurality of locations; wherein a plurality of locations along the wire where a resource is located have electrical connections that are grounded; wherein a plurality of locations along the wire where a resource is not located have electrical connections that are open; receiving a reflection of the TDR signal at the first location; and based upon the received reflection of the TDR signal, determining a subset of the plurality of locations in the rack at which resources are located.

Example 94 may include the subject matter of example 93, wherein the TDR signal is a shaped electrical wave or an electrical pulse.

Example 95 may be one or more computer-readable media comprising instructions a cause a computing device, in response to execution of the instructions by the computing device, to: cause a voltage to be applied at a first location along a resistive wire with a known resistance per length of the resistive wire that traverses a plurality of locations on the rack at which resources are located; measure a voltage at a second location along the resistive wire; and cause characteristics of the voltage applied at the first location and characteristics of the voltage measured at the second location to be compared; wherein based upon the comparison, a location of the resource within the rack is identified; and wherein the first location or the second location is the location of the resource in the rack.

Example 96 may include the subject matter of example 95, wherein the first location is an end of the resistive wire and the second location is the location of the resource in the rack; and wherein to cause a voltage to be applied at a first location further comprises causing a switch to be closed to connect a voltage source with the resistive wire at the first location.

Example 97 may include the subject matter of example 96, wherein the switch and the resource location module are coupled.

Example 98 may include the subject matter of example 95, wherein to cause a voltage to be applied at a first location further comprises to cause a resource located in the rack to apply the voltage at the first location.

Example 99 may include the subject matter of any one of examples 95-98, wherein the resistive wire is a high resistance wire or carbon resistor ignition cable with resistance properties measured in ohms per foot.

Example 100 may include the subject matter of any one of examples 95-98, wherein the resistive wire is a wire with resistors placed evenly along the wire.

Example 101 may include the subject matter of any one of examples 95-98, wherein the resistive wire is a wire with resistors placed at each U position within the rack.

Example 102 may be one or more computer-readable media comprising instructions a cause a computing device, in response to execution of the instructions by the computing device, to: cause a current to be applied by a resource at a location along a resistive wire with a known resistance per length of the resistive wire that traverses a plurality of locations on the rack at which resources are located with one end of the resistive wire connected to ground; and cause a voltage to be measured at the location; and identify, based upon the measured voltage, the location of the resource within the rack.

Example 103 may include the subject matter of example 102, wherein the resistive wire is a high resistance wire or carbon resistor ignition cable with resistance properties measured in ohms per foot.

Example 104 may include the subject matter of example 102, wherein the resistive wire is a wire with resistors placed evenly along the wire.

Example 105 may include the subject matter of example 102, wherein the resistive wire is a wire with resistors placed at each U position within the rack.

Example 106 may be one or more computer-readable media comprising instructions a cause a computing device, in response to execution of the instructions by the computing device, to: cause a light to enter a first location along a light pipe that traverses a plurality of locations on the rack at which resources are located; receive light at a second location along the light pipe; and compare characteristics of the light at the first location and characteristics of the light at the second location; based upon the comparison, to identify a location of the resource within the rack is identified; and wherein the first location or the second location is the location of the resource in the rack.

Example 107 may include the subject matter of example 106, wherein the light pipe attenuates light by a determined amount over a known distance of the light pipe; and wherein comparing further includes comparing an intensity of the light at the first location with an intensity of light at the second location.

Example 108 may include the subject matter of any one of examples 106-107, wherein the first location along the light pipe is an end of the light pipe and the second location along the light pipe is at the location of the resource.

Example 109 may include the subject matter of any one of examples 106-107, wherein the first location along the light pipe is at the location of the resource and the second location along the light pipe is at an end of the light pipe.

Example 110 may be one or more computer-readable media comprising instructions a cause a computing device, in response to execution of the instructions by the computing device, to: cause a light to enter a first location of a resource within a rack along a light pipe that traverses a plurality of locations on the rack at which resources are located; and identify a wavelength of the light at a second location along the light pipe; determined, based upon the identified wavelength, a location of the resource within the rack.

Example 111 may include the subject matter of example 110, wherein the first location along the light pipe is an end of the light pipe and the second location along the light pipe is at the location of the resource.

Example 112 may include the subject matter of example 110, wherein the first location along the light pipe is at the location of the resource and the second location along the light pipe is at an end of the light pipe.

Example 113 may be one or more computer-readable media comprising instructions a cause a computing device, in response to execution of the instructions by the computing device, to: cause an audio signal to be transmitted at a first location along an acoustical waveguide that traverses a plurality of locations on the rack at which resources are located; deploy at a second location, a reflector to reflect the audio signal back along the acoustical waveguide to be received at the first location; and cause characteristics of the audio signal as transmitted and the audio signal as received to be compared; determined, based upon the comparison, a location of the resource within the rack.

Example 114 may include the subject matter of example 113, wherein the first location along the acoustical waveguide is an end of the light pipe and the second location along the acoustical waveguide is at the location of the resource.

Example 115 may include the subject matter of example 113, wherein the first location along the acoustical waveguide is at the location of the resource and the second location along the acoustical waveguide is at an end of the light pipe.

Example 116 may be one or more computer-readable media comprising instructions a cause a computing device, in response to execution of the instructions by the computing device, to: cause an audio signal to be transmitted at a first location along an acoustical waveguide that traverses a plurality of locations on the rack at which resources are located, wherein the acoustical waveguide is to attenuate the audio signal by a determined amount over a known distance of the acoustical waveguide; receive at a second location along the acoustical waveguide, an audio signal; and compare characteristics of the audio signal as transmitted and the audio signal as received; identify, based upon the comparison, a location of the resource within the rack; and wherein the first location or the second location is the location of the resource in the rack.

Example 117 may include the subject matter of example 116, wherein the first location along the acoustical waveguide is an end of the acoustical waveguide and the second location along the acoustical waveguide is at the location of the resource.

Example 118 may include the subject matter of example 116, wherein the first location along the acoustical waveguide is at the location of the resource and the second location along the acoustical waveguide is at an end of the acoustical waveguide.

Example 119 may be one or more computer-readable media comprising instructions a cause a computing device, in response to execution of the instructions by the computing device, to: cause an audio signal to be transmitted at a first location of a resource within a rack along an acoustical waveguide that traverses a plurality of locations on the rack at which resources are located; and identify a wavelength of the audio signal at a second location along the acoustical waveguide; wherein based upon the identified wavelength, a location of the resource within the rack is identified and wherein the first location or the second location is the location of the resource in the rack.

Example 120 may include the subject matter of example 119, wherein the first location along the acoustical waveguide is an end of the acoustical waveguide and the second location along the acoustical waveguide is at the location of the resource.

Example 121 may include the subject matter of example 119, wherein the first location along the acoustical waveguide is at the location of the resource and the second location along the acoustical waveguide is at an end of the acoustical waveguide.

Example 122 may be one or more computer-readable media comprising instructions a cause a computing device, in response to execution of the instructions by the computing device, to: cause an electromagnetic signal to be transmitted at a first location along an electromagnetic waveguide that traverses a plurality of locations on the rack at which resources are located; and cause characteristics of the electromagnetic signal to be identified at a second location along the electromagnetic waveguide; wherein based upon the identified characteristics, a location of the resource within the rack is identified; and wherein the first location or the second location is the location of the resource in the rack.

Example 123 may include the subject matter of example 122, wherein the electromagnetic waveguide is to attenuate the electromagnetic signal by a determined amount over a known distance of the electromagnetic waveguide.

Example 124 may include the subject matter of example 122, wherein one of the identified characteristics of the electromagnetic signal is a wavelength.

Example 125 may include the subject matter of any one of examples 122-124, wherein the first location along the electromagnetic waveguide is an end of the electromagnetic waveguide and the second location along the electromagnetic waveguide is at the location of the resource.

Example 126 may include the subject matter of any one of examples 122-124, wherein the first location along the electromagnetic waveguide is at the location of the resource and the second location along the electromagnetic waveguide is at an end of the electromagnetic waveguide.

Example 127 may be one or more computer-readable media comprising instructions a cause a computing device, in response to execution of the instructions by the computing device, to: cause a data value to be transmitted at a first location along a data bus with one or more data modifiers located on the data bus at regular intervals that traverses a plurality of locations on the rack at which resources are located; cause a data value to be identified at a second location along the data bus; and compare the data value at the first location and the data value at the second; wherein based upon the comparison, a location of the resource within the rack is identified; and wherein the first location or the second location is the location of the resource in the rack.

Example 128 may include the subject matter of example 127, wherein the first location is at an end of the data bus and the second location is at the location of the resource.

Example 129 may include the subject matter of example 127, wherein the first location is at the location of the resource and the second location is at an end of the data bus.

Example 130 may include the subject matter of any one of examples 127-129, wherein the data modifier is an adder, a subtractor or a bit shifter.

Example 131 may include the subject matter of example 130, wherein the data modifiers are located on the data bus at each U position of the rack.

Example 132 may be one or more computer-readable media comprising instructions a cause a computing device, in response to execution of the instructions by the computing device, to: cause a signal to be transmitted from a first location on a path that traverses a plurality of locations on the rack at which resources may be located, to a signal reflector at a second location, wherein the reflected signal is to be received at the first location; and compare characteristics of the signal as transmitted and as received after reflection; wherein based upon the comparison, the location of the resource within the rack is identified.

Example 133 may include the subject matter of example 132, wherein the transmitted signal and the reflected signal travel on a signal transmission medium (STM).

Example 134 may include the subject matter of example 132, wherein the first location is a location of the resource in the rack and the signal reflector is at a known location proximate to the rack.

Example 135 may include the subject matter of example 132, wherein the first location is a known location proximate to the rack; and wherein the signal reflector is coupled to the resource.

Example 136 may include the subject matter of example 135, further comprising to cause the signal reflector to physically deploy from the resource to reflect the transmitted signal back to the first location.

Example 137 may include the subject matter of any one of examples 132-136, wherein to compare characteristics of the signal as transmitted and the signal as received after reflection further includes to compare a phase of the transmitted signal and a phase of the signal as received.

Example 138 may include the subject matter of any one of examples 132-136, wherein the signal as transmitted and the signal as received after reflection are light signals, acoustical signals, or electromagnetic signals.

Example may be one or more computer-readable media comprising instructions a cause a computing device, in response to execution of the instructions by the computing device, to: cause a time domain reflectometer (TDR) signal to be transmitted from a first location along an electrically conductive wire that traverses a plurality of locations in the rack at which resources may be located, the conductive wire having electrical connections respectively at each of the plurality of locations; wherein a plurality of locations along the wire where a resource is located have electrical connections that are grounded; wherein a plurality of locations along the wire where a resource is not located have electrical connections that are open; receive a reflection of the TDR signal at the first location; and based upon the received reflection of the TDR signal, to determine a subset of the plurality of locations in the rack at which resources are located.

Example 140 may include the subject matter of example 139, wherein the TDR signal is a shaped electrical wave or an electrical pulse.

Example 141 may be an apparatus to identify a location of a resource among a plurality of locations in a rack, comprising: means for causing a voltage to be applied at a first location along a resistive wire with a known resistance per length of the resistive wire that traverses a plurality of locations on the rack at which resources are located; means for measuring a voltage at a second location along the resistive wire; and means for causing characteristics of the voltage applied at the first location and characteristics of the voltage measured at the second location to be compared; wherein based upon the comparison, a location of the resource within the rack is identified; and wherein the first location or the second location is the location of the resource in the rack.

Example 142 may include the apparatus of example 141, wherein the first location is an end of the resistive wire and the second location is the location of the resource in the rack; and wherein means for causing a voltage to be applied at a first location further comprises means for causing a switch to be closed to connect a voltage source with the resistive wire at the first location.

Example 143 may include the apparatus of example 2, wherein the switch and the resource location module are coupled.

Example 144 may include the apparatus of example 141, wherein means for causing a voltage to be applied at a first location further comprises means for causing a resource located in the rack to apply the voltage at the first location.

Example 145 may include the apparatus of any one of examples 141-144, wherein the resistive wire is a high resistance wire or carbon resistor ignition cable with resistance properties measured in ohms per foot.

Example 146 may include the apparatus of any one of examples 141-144, wherein the resistive wire is a wire with resistors placed evenly along the wire.

Example 147 may include the apparatus of any one of examples 141-144, wherein the resistive wire is a wire with resistors placed at each U position within the rack.

Example 148 may be an apparatus to identify a location of a resource among a plurality of locations in a rack, comprising: means for causing a current to be applied by a resource at a location along a resistive wire with a known resistance per length of the resistive wire that traverses a plurality of locations on the rack at which resources are located with one end of the resistive wire connected to ground; and means for causing a voltage to be measured at the location; and means for identifying, based upon the measured voltage, the location of the resource within the rack.

Example 149 may include the apparatus of example 148, wherein the resistive wire is a high resistance wire or carbon resistor ignition cable with resistance properties measured in ohms per foot.

Example 150 may include the apparatus of example 148, wherein the resistive wire is a wire with resistors placed evenly along the wire.

Example 151 may include the apparatus of example 148, wherein the resistive wire is a wire with resistors placed at each U position within the rack.

Example 152 may be an apparatus to identify a location of a resource among a plurality of locations in a rack, comprising: means for causing a light to enter a first location along a light pipe that traverses a plurality of locations on the rack at which resources are located; means for receiving light at a second location along the light pipe; and means for comparing characteristics of the light at the first location and characteristics of the light at the second location; based upon the comparison, means for identifying a location of the resource within the rack is identified; and wherein the first location or the second location is the location of the resource in the rack.

Example 153 may include the apparatus of example 152, wherein the light pipe attenuates light by a determined amount over a known distance of the light pipe; and wherein means for comparing further includes means for comparing an intensity of the light at the first location with an intensity of light at the second location.

Example 154 may include the apparatus of any one of examples 152-153, wherein the first location along the light pipe is an end of the light pipe and the second location along the light pipe is at the location of the resource.

Example 155 may include the apparatus of any one of examples 152-153, wherein the first location along the light pipe is at the location of the resource and the second location along the light pipe is at an end of the light pipe.

Example 156 may be an apparatus to identify a location of a resource among a plurality of locations in a rack, comprising: means for causing a light to enter a first location of a resource within a rack along a light pipe that traverses a plurality of locations on the rack at which resources are located; means for identifying a wavelength of the light at a second location along the light pipe; and means for determining, based upon the identified wavelength, a location of the resource within the rack.

Example 157 may include the apparatus of example 156, wherein the first location along the light pipe is an end of the light pipe and the second location along the light pipe is at the location of the resource.

Example 158 may include the apparatus of example 156, wherein the first location along the light pipe is at the location of the resource and the second location along the light pipe is at an end of the light pipe.

Example 159 may include an apparatus to identify a location of a resource among a plurality of locations in a rack, comprising: means for causing an audio signal to be transmitted at a first location along an acoustical waveguide that traverses a plurality of locations on the rack at which resources are located; means for deploying at a second location, a reflector to reflect the audio signal back along the acoustical waveguide to be received at the first location; means for causing characteristics of the audio signal as transmitted and the audio signal as received to be compared; and means for determining, based upon the comparison, a location of the resource within the rack.

Example 160 may include the apparatus of example 159, wherein the first location along the acoustical waveguide is an end of the light pipe and the second location along the acoustical waveguide is at the location of the resource.

Example 161 may include the apparatus of example 159, wherein the first location along the acoustical waveguide is at the location of the resource and the second location along the acoustical waveguide is at an end of the light pipe.

Example 162 may include an apparatus to identify a location of a resource among a plurality of locations in a rack, comprising: means for causing an audio signal to be transmitted at a first location along an acoustical waveguide that traverses a plurality of locations on the rack at which resources are located, wherein the acoustical waveguide is to attenuate the audio signal by a determined amount over a known distance of the acoustical waveguide; means for receiving at a second location along the acoustical waveguide, an audio signal; means for comparing characteristics of the audio signal as transmitted and the audio signal as received; means for identifying, based upon the comparison, a location of the resource within the rack; and wherein the first location or the second location is the location of the resource in the rack.

Example 163 may include the apparatus of example 162, wherein the first location along the acoustical waveguide is an end of the acoustical waveguide and the second location along the acoustical waveguide is at the location of the resource.

Example 164 may include the apparatus of example 162, wherein the first location along the acoustical waveguide is at the location of the resource and the second location along the acoustical waveguide is at an end of the acoustical waveguide.

Example 165 may be an apparatus to identify a location of a resource among a plurality of locations in a rack, comprising: means for causing an audio signal to be transmitted at a first location of a resource within a rack along an acoustical waveguide that traverses a plurality of locations on the rack at which resources are located; means for identifying a wavelength of the audio signal at a second location along the acoustical waveguide; wherein based upon the identified wavelength, a location of the resource within the rack is identified and wherein the first location or the second location is the location of the resource in the rack.

Example 166 may include the apparatus of example 165, wherein the first location along the acoustical waveguide is an end of the acoustical waveguide and the second location along the acoustical waveguide is at the location of the resource.

Example 167 may include the apparatus of example 165, wherein the first location along the acoustical waveguide is at the location of the resource and the second location along the acoustical waveguide is at an end of the acoustical waveguide.

Example 168 may be an apparatus to identify a location of a resource among a plurality of locations in a rack, comprising: means for causing an electromagnetic signal to be transmitted at a first location along an electromagnetic waveguide that traverses a plurality of locations on the rack at which resources are located; means for causing characteristics of the electromagnetic signal to be identified at a second location along the electromagnetic waveguide; wherein based upon the identified characteristics, a location of the resource within the rack is identified; and wherein the first location or the second location is the location of the resource in the rack.

Example 169 may include the apparatus of example 168, wherein the electromagnetic waveguide is to attenuate the electromagnetic signal by a determined amount over a known distance of the electromagnetic waveguide.

Example 170 may include the apparatus of example 168, wherein one of the identified characteristics of the electromagnetic signal is a wavelength.

Example 171 may include the apparatus of any one of examples 168-170, wherein the first location along the electromagnetic waveguide is an end of the electromagnetic waveguide and the second location along the electromagnetic waveguide is at the location of the resource.

Example 172 may include the apparatus of any one of examples 168-170, wherein the first location along the electromagnetic waveguide is at the location of the resource and the second location along the electromagnetic waveguide is at an end of the electromagnetic waveguide.

Example 173 may be an apparatus to identify a location of a resource among a plurality of locations in a rack, comprising: means for causing a data value to be transmitted at a first location along a data bus with one or more data modifiers located on the data bus at regular intervals that traverses a plurality of locations on the rack at which resources are located; means for causing a data value to be identified at a second location along the data bus; means for comparing the data value at the first location and the data value at the second; wherein based upon the comparison, a location of the resource within the rack is identified; and wherein the first location or the second location is the location of the resource in the rack.

Example 174 may include the apparatus of example 173, wherein the first location is at an end of the data bus and the second location is at the location of the resource.

Example 175 may include the apparatus of example 173, wherein the first location is at the location of the resource and the second location is at an end of the data bus.

Example 176 may include the apparatus of any one of examples 173-175, wherein the data modifier is an adder, a subtractor or a bit shifter.

Example 177 may include the apparatus of example 176, wherein the data modifiers are located on the data bus at each U position of the rack.

Example 178 may include an apparatus for identifying a location of a resource among a plurality of locations in a rack, comprising: means for causing a signal to be transmitted from a first location on a path that traverses a plurality of locations on the rack at which resources may be located, to a signal reflector at a second location, wherein the reflected signal is to be received at the first location; means for comparing characteristics of the signal as transmitted and as received after reflection; wherein based upon the comparison, the location of the resource within the rack is identified.

Example 179 may include the apparatus of example 178, wherein the transmitted signal and the reflected signal travel on a signal transmission medium (STM).

Example 180 may include the apparatus of example 178, wherein the first location is a location of the resource in the rack and the signal reflector is at a known location proximate to the rack.

Example 181 may include the apparatus of example 178, wherein the first location is a known location proximate to the rack; and wherein the signal reflector is coupled to the resource.

Example 182 may include the apparatus of example 181, further comprising means for causing the signal reflector to physically deploy from the resource to reflect the transmitted signal back to the first location.

Example 183 may include the apparatus of any one of examples 178-182, wherein comparing characteristics of the signal as transmitted and the signal as received after reflection further includes means for comparing a phase of the transmitted signal and a phase of the signal as received.

Example 184 may include the apparatus of any one of examples 178-182, wherein the signal as transmitted and the signal as received after reflection are light signals, acoustical signals, or electromagnetic signals.

Example 185 may be an apparatus to identify resources among a plurality of locations in a rack, comprising: means for causing a time domain reflectometer (TDR) signal to be transmitted from a first location along an electrically conductive wire that traverses a plurality of locations in the rack at which resources may be located, the conductive wire having electrical connections respectively at each of the plurality of locations; wherein a plurality of locations along the wire where a resource is located have electrical connections that are grounded; wherein a plurality of locations along the wire where a resource is not located have electrical connections that are open; means for receiving a reflection of the TDR signal at the first location; and based upon the received reflection of the TDR signal, means for determining a subset of the plurality of locations in the rack at which resources are located.

Example 186 may include the apparatus of example 185, wherein the TDR signal is a shaped electrical wave or an electrical pulse.

What is claimed is:

1. An apparatus to identify a location of a resource among a plurality of locations in a data center rack, comprising:
one or more processors; and
a resource location module coupled with the processors to:
cause a signal to be transmitted from a first location along a signal transmission medium (STM) that traverses a plurality of locations on the data center rack at which resources are located, wherein the signal is to be received at a second location along the STM;
cause the transmitted signal and the received signal to be compared;
based upon the comparison, identify the location of the resource within the data center rack;
wherein the first location or the second location is a location of the resource in the data center rack; and
wherein the first location and the second location are different locations.

2. The apparatus of claim 1, wherein the apparatus is included within a resource management module (RMM) or within a resource located in the data center rack.

3. The apparatus of claim 1, wherein the STM is a conductive wire with a known resistance per length of the wire;
wherein to cause a signal to be transmitted from a first location further includes to cause a first voltage to be applied at an end of the STM;
wherein the signal to be received at a second location along the STM further includes a second voltage at a location of the resource in the data center rack; and
wherein to cause the transmitted signal and the received signal to be compared further includes to cause the first voltage and the second voltage to be compared.

4. The apparatus of claim 3, wherein the resource location module is further to switch the first voltage on or off when the location of the resource in the data center rack is to be identified.

5. The apparatus of claim 1, wherein the STM is a conductive wire with a known resistance per length of the wire;
wherein to cause a signal to be transmitted from a first location further includes to cause a first voltage to be applied on the STM at the location of the resource in the data center rack;
wherein the signal to be received at a second location along the STM further includes to apply a second voltage at an end of the STM; and
wherein to cause the transmitted signal and the received signal to be compared further includes to cause the first voltage and the second voltage to be compared.

6. The apparatus of claim 5, wherein the resource is to apply the first voltage on the STM at the location of the resource in the data center rack.

7. The apparatus of claim 3, wherein the STM is a high resistance wire or a carbon resistor ignition cable with resistance properties measured in ohms per foot.

8. The apparatus of claim 3, wherein the STM is a wire with resistors placed in evenly along the wire.

9. The apparatus of claim 3, wherein the STM is a wire with resistors placed at each U position within the data center rack.

10. An apparatus for identifying a location of a resource among a plurality of locations in a data center rack, comprising:
one or more processors;
a resource location module coupled to the one or more processors to:
sense a voltage on a signal transmission medium (STM) disposed proximate to the plurality of locations in the data center rack to transmit a signal traversing the plurality of locations by a sensor portion of the resource coupled to the STM substantially at the resource location; and
identify the location of the resource based upon the sensed voltage; and
wherein the apparatus is included within the resource.

11. The apparatus of claim 10, wherein the STM includes at least one resistor between each of the plurality of locations in the data center rack.

12. The apparatus of claim 10, wherein the resource location module is further to apply a voltage on the STM.

13. The apparatus of claim 12, wherein the resource location module is further to apply a voltage on the STM when the location of the resource is to be determined.

14. An apparatus for identifying a location of a resource among a plurality of locations in a data center rack, comprising:
a signal transmission medium (STM) disposed proximate to the plurality of locations in the data center rack to transmit a signal traversing the plurality of locations;
wherein, when a resource is positioned in the location in the data center rack, a sensor portion of the resource couples itself to the STM at a point substantially at the location and senses the transmitted signal on the signal transmission medium; and
wherein the location of the resource within the data center rack is identified based at least in part on the sensed signal.

15. The apparatus of claim 14, wherein the signal on the STM has a limited duration.

16. The apparatus of claim 15, wherein the limited duration is determined by the resource or by a rack management module (RMM).

17. The apparatus of claim 14, wherein the STM is an electrically conductive wire along a length of the data center rack with a known resistance proportional to the length of the wire; and
wherein the sensor is to measure voltage on the signal transmission medium.

18. The apparatus of claim 17, wherein one end of the electrically conductive wire is at a reference voltage.

19. The apparatus of claim 14, wherein the resource is a server.

20. A method for identifying a location of a resource among a plurality of locations in a data center rack, comprising:
applying a voltage on a signal transmission medium (STM) disposed proximate to the plurality of locations in a data center rack to transmit a signal traversing the plurality of locations;
sensing a voltage on the STM by a sensor portion of the resource coupled to the STM substantially at the resource location; and
identifying the location of the resource based upon the sensed voltage.

21. The method of claim 20, wherein the STM includes at least one resistor between each of the plurality of locations in the data center rack.

22. The method of claim 20, wherein the voltage is sensed using an analog to digital converter (ADC).

23. The method of claim 20, wherein applying a voltage further includes applying a voltage when the location of the resources is to be determined.
